(19) United States
(12) Patent Application Publication
(10) Pub. No.: US 2024/0146290 A1
(43) Pub. Date: May 2, 2024

(54) LIGHT SOURCE DRIVE CIRCUIT AND DISTANCE MEASURING DEVICE

(71) Applicant: SONY SEMICONDUCTOR SOLUTIONS CORPORATION, KANAGAWA (JP)

(72) Inventors: TAKASHI MASUDA, KANAGAWA (JP); DAISUKE SUZUKI, KANAGAWA (JP); MITSUSHI TABATA, KANAGAWA (JP); KOICHI OKAMOTO, KANAGAWA (JP); KOUTA HIYAMA, KANAGAWA (JP)

(21) Appl. No.: 18/548,825

(22) PCT Filed: Mar. 2, 2022
(86) PCT No.: PCT/JP2022/008990

§ 371 Date: Sep. 1, 2023

(30) Foreign Application Priority Data
Mar. 12, 2021 (JP) 2021-040384

(51) Int. Cl. H03K 5/133; G01S 7/484; H01S 5/042; H03L 7/081; H03K 5/00

(52) U.S. Cl. CPC H03K 5/133; G01S 7/484; H01S 5/042; H03L 7/0818; H03K 2005/00019

(57) ABSTRACT

A light source drive circuit according to an embodiment includes: a first delay circuit (10) that gives, based on a clock signal, a delay to an input signal with first time resolution and a second delay circuit (20) that is connected in series to the first delay circuit, gives, based on the clock signal, a delay to an input signal with a second time resolution having accuracy different from accuracy of the first time resolution, and outputs the signal as a signal for driving a light source.

### FIELD

The present disclosure relates to a light source drive circuit and a distance measuring device.

### BACKGROUND

There has been known a delay synchronization circuit that delays an input signal in synchronization with a clock. As the delay synchronization circuit, there has been known, for example, a configuration in which delay circuits that delay an input signal in units of clocks are connected in series by a desired number of delay amounts and phases of outputs of the delay circuits connected in series and the input signal are compared to lock the delay amounts.

Incidentally, there has been known a distance measuring scheme called time of flight (ToF) for measuring a distance to a measurement object based on a difference between timing when light is emitted by a light source and timing when reflected light of the light reflected on the measurement object is received. The light emission timing can be controlled by delaying, by a known delay amount, a light emission trigger signal for instructing light emission of the light source. In the ToF scheme, since distance measurement is performed based on the speed of light, it is necessary to control the light emission timing with high accuracy.

### CITATION LIST

### Patent Literature

Patent Literature 1: JP 2008-219535 A

### SUMMARY

### Technical Problem

In a delay synchronization circuit according to the related art, in general, a delay circuit is configured using an inverter circuit. In this configuration, a large-scale circuit is required in order to realize a large delay width with high resolution delay accuracy. Therefore, the number of delay circuits to be used increases, the delay synchronization circuit is easily affected by environmental changes such as process variations, temperature changes, and fluctuations in a power supply voltage, and it is difficult to maintain accuracy.

An object of the present disclosure is to provide a light source drive circuit and a distance measuring device capable of realizing more accurate timing control with a relatively small-scale circuit configuration.

### Solution to Problem

For solving the problem described above, a light source drive circuit according to one aspect of the present disclosure has a first delay circuit that gives, based on a clock signal, a delay to an input signal with first time resolution; and a second delay circuit that is connected in series to the first delay circuit, gives, based on the clock signal, a delay to an input signal with second time resolution having accuracy different from accuracy of the first time resolution, and outputs the signal as a signal for driving a light source.

### BRIEF DESCRIPTION OF DRAWINGS

FIG. 1 is a block diagram illustrating a schematic configuration of a light source drive circuit according to the present disclosure.

FIG. 2 is a block diagram illustrating a configuration of an example of a light source drive circuit according to an existing technology.

FIG. 3 is a block diagram illustrating a configuration of an example of a light source drive circuit according to a first embodiment.

FIG. 4A is a diagram illustrating a configuration of an example of a coarse delay circuit applicable to the first embodiment.

FIG. 4B is an exemplary sequence chart for explaining an operation of the coarse delay circuit applicable to the first embodiment.

FIG. 5 is a diagram illustrating a configuration of an example of a fine delay circuit applicable to the first embodiment.

FIG. 6 is a diagram illustrating a configuration of another example of the fine delay circuit applicable to the first embodiment.

FIG. 7 is a diagram more specifically illustrating a configuration of an example of the light source drive circuit according to the first embodiment.

FIG. 8 is a sequence chart illustrating an example of an operation of the light source drive circuit according to the first embodiment.

FIG. 9A is a block diagram illustrating a schematic configuration example of a phase comparison circuit according to the first embodiment.

FIG. 9B is a block diagram illustrating a more specific configuration example of a phase comparison circuit applicable to the first embodiment.

FIG. 10A is a sequence chart for explaining an example of an operation of the phase comparison circuit according to the first embodiment.

FIG. 10B is a sequence chart for explaining an example of an operation of the phase comparison circuit according to the first embodiment.

FIG. 11 is a sequence chart for explaining another example of the operation of the phase comparison circuit according to the first embodiment.

FIG. 12 is a block diagram illustrating a configuration of an example of a light source drive circuit according to a first modification of the first embodiment.

FIG. 13 is a diagram illustrating a first example of a coarse delay circuit applicable to the first modification of the first embodiment.

FIG. 14 is a diagram illustrating a second example of the coarse delay circuit applicable to the first modification of the first embodiment.

FIG. 15 is a schematic diagram for explaining an operation according to the second example of the coarse delay circuit applicable to the first modification of the first embodiment.

FIG. 16 is a diagram illustrating a third example of the coarse delay circuit applicable to the first modification of the first embodiment.

FIG. 17A is a block diagram illustrating a configuration of an example of a light source drive circuit according to a second modification of the first embodiment.

FIG. 17B is a block diagram illustrating a configuration of another example of the light source drive circuit according to the second modification of the first embodiment.

FIG. 18 is a block diagram illustrating a configuration of an example of a light source drive circuit according to a third modification of the first embodiment.

FIG. 19 is a block diagram illustrating a configuration of an example of a light source drive circuit according to a fourth modification of the first embodiment.

FIG. 20A is a diagram schematically illustrating an implementation example of an LD driver and an LD array according to a second embodiment.

FIG. 20B is a diagram schematically illustrating an implementation example of the LD driver and the LD array according to the second embodiment.

FIG. 20C is a diagram schematically illustrating an implementation example of the LD driver and the LD array according to the second embodiment.

FIG. 21 is a schematic diagram illustrating an example of disposition positions of LD drivers with respect to an LDD chip according to the second embodiment.

FIG. 22 is a block diagram illustrating a configuration of an example of a distance measuring device applicable to a third embodiment.

FIG. 23 is a diagram for explaining a principle of an indirect ToF scheme.

FIG. 24 is a diagram illustrating an example of a case in which light emitted from a light source unit 311 is a rectangular wave modulated by PWM.

FIG. 25 is a block diagram illustrating, more in detail, a configuration example of a distance measuring unit applicable to the third embodiment.

### DESCRIPTION OF EMBODIMENTS

Embodiments of the present disclosure are explained in detail below with reference to the drawings. Note that, in the embodiments explained below, redundant explanation is omitted by denoting the same parts with the same reference numerals and signs.

The embodiments of the present disclosure are explained in detail below according to the following order.
1. Schematic explanation of the present disclosure
2. Existing Technology
3. First embodiment of the present disclosure
3-0-1. Configuration according to the first embodiment
3-0-2. Operation according to the first embodiment
3-1. First modification of the first embodiment
3-1-1. First example of the first modification of the first embodiment
3-1-2. Second example of the first modification of the first embodiment
3-1-3. Third example of the first modification of the first embodiment
3-2. Second modification of the first embodiment of the present disclosure
3-3. Third modification of the first embodiment of the present disclosure
3-4. Fourth modification of the first embodiment of the present disclosure
4. Second embodiment of the present disclosure
5. Third embodiment of the present disclosure
5-1. Schematic explanation of indirect ToF
5-2. Configuration example for implementing indirect ToF

### 1. Schematic Explanation of the Present Disclosure

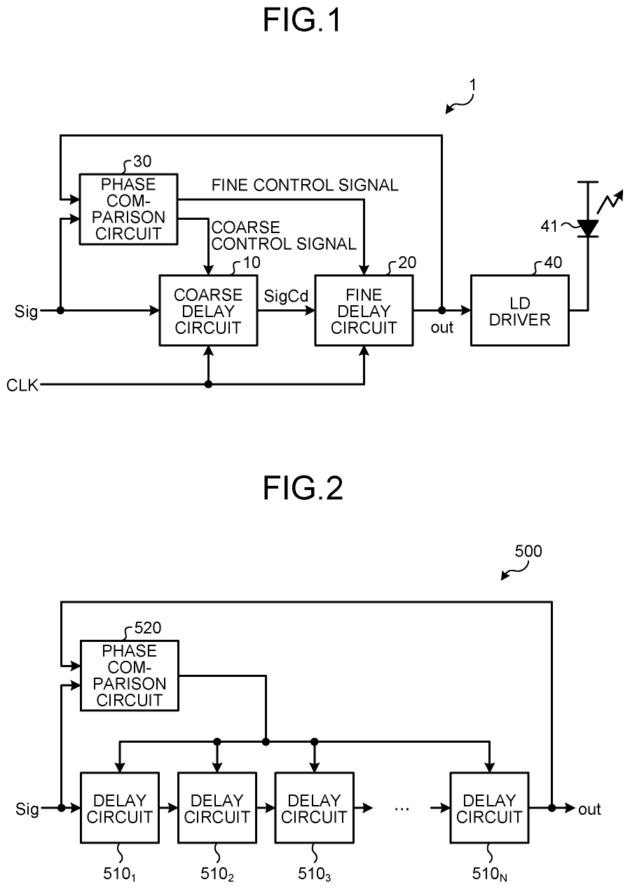

First, a technology according to the present disclosure is schematically explained. FIG. 1 is a block diagram illustrating a schematic configuration of a light source drive circuit according to the present disclosure. In FIG. 1, a light source drive circuit 1 according to the present disclosure includes a coarse delay circuit 10 and a fine delay circuit 20.

A signal Sig for driving a laser diode (LD) 41 explained below is input to the coarse delay circuit 10 (a first delay circuit). The signal Sig is a periodic signal. For example, a pulse width modulation (PWM) signal can be applied to the signal Sig. The coarse delay circuit 10 delays the input signal Sig by a delay amount of time resolution (first time resolution) corresponding to a cycle of a clock signal CLK and outputs the signal Sig as a signal SigCd. Note that, at this time, the coarse delay circuit 10 can output the signal SigCd with a phase shifted in units of 90°.

The signal SigCd output from the coarse delay circuit 10 is input to the fine delay circuit 20 (a second delay circuit). The fine delay circuit 20 delays the input signal SigCd by a delay amount of time resolution (second time resolution) smaller than the cycle of the clock signal CLK and outputs the signal SigCd as an output signal out. For example, the fine delay circuit 20 delays the signal SigCd by a delay amount corresponding to any phase angle at least in a range of a phase angle of 0° to 90° and outputs the signal SigCd as the output signal out.

The output signal out output from the fine delay circuit 20 is supplied to an LD driver 40. The LD driver 40 generates, according to the output signal out, a drive signal for driving an LD 41 functioning as a light source. The LD 41 is driven according to a drive signal supplied from the LD driver 40 and emits light.

The light source drive circuit 1 according to the present disclosure further includes a phase comparison circuit 30. The phase comparison circuit 30 compares a phase (a second phase) based on the signal Sig with a phase (a first phase) based on the output signal out of the fine delay circuit 20 and generates, based on a comparison result, a coarse control signal for controlling a delay by the coarse delay circuit 10 and a fine control signal for controlling a delay by the fine delay circuit 20. The phase comparison circuit 30 supplies the generated coarse control signal and the generated fine control signal respectively to the coarse delay circuit 10 and the fine delay circuit 20.

As explained above, the light source drive circuit 1 according to the present disclosure gives, to the input signal Sig, with the coarse delay circuit 10, a delay in units of the cycle of the clock signal CLK and further gives, with the fine delay circuit 20, to an output of the coarse delay circuit 10, a delay with time resolution smaller than the cycle of the clock signal CLK. The light source drive circuit 1 drives the LD 41 according to the output signal out output from the fine delay circuit 20.

Therefore, by applying the light source drive circuit 1 according to the present disclosure, it is possible to control light emission timing of the LDs 41 with higher accuracy using a relatively small-scale circuit configuration.

### 2. Existing Technology

Next, prior to explanation of the embodiments of the present disclosure, an existing technology is explained to facilitate understanding.

FIG. 2 is a block diagram illustrating a configuration of an example of a light source drive circuit according to the existing technology. In FIG. 2, a light source drive circuit 500 includes a plurality of delay circuits 510₁, 510₂, 510₃, . . . , and 510_{N} connected in series, which respectively give delays by predetermined delay amounts to input signals, and a phase comparison circuit 520. Note that, in FIG. 2, a light source driven by the output signal out of the light source drive circuit 500 is omitted.

The signal Sig, which is a periodic signal, is input to the delay circuit 510₁ and is input to one input end of the phase comparison circuit 520. The signal Sig is given delays of delay amounts corresponding to the cycle of the signal Sig respectively by the delay circuits 510₁ to 510_{N} and is output as the output signal out from the delay circuit 510_{N}. The output signal out is input to the other input end of the phase comparison circuit 520.

The phase comparison circuit 520 compares a phase of the signal Sig input to one input end and a phase of the output signal out input to the other input end and controls the delays by the delay circuits 510₁ to 510_{N} based on a comparison result. According to the control of the phase comparison circuit 520, the delay amount of the output signal out with respect to the signal Sig becomes equal to the cycle compared in the phase comparison circuit 520.

In the example illustrated in FIG. 2, the delay circuit 510₁ to 510_{N} are respectively configured by, for example, inverter circuits. Therefore, a large-scale circuit is necessary in order to gain a delay width with delay accuracy of high time resolution and the number of delay circuits to be used increases. Therefore, the light source drive circuit 500 is easily affected by environmental changes such as variations due to a manufacturing process, temperature changes, and power supply voltage fluctuations and it is difficult to maintain accuracy.

### 3. First Embodiment of the Present Disclosure

Subsequently, a first embodiment of the present disclosure is explained.

(3-0-1. Configuration According to the First Embodiment)

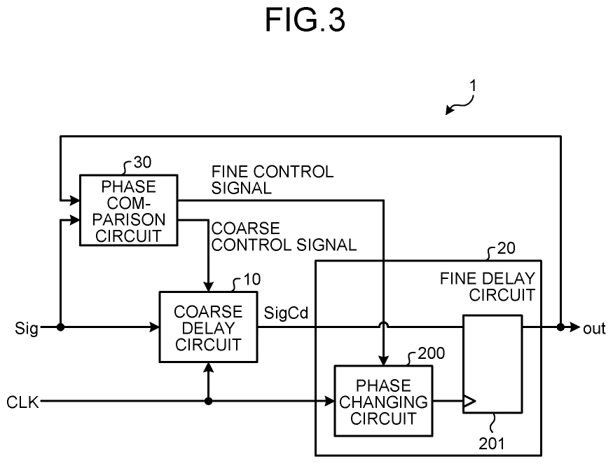

First, a configuration of a light source drive circuit according to a first embodiment is explained. FIG. 3 is a block diagram illustrating a configuration of an example of the light source drive circuit according to the first embodiment. The configuration illustrated in FIG. 3 corresponds to the configuration explained with reference to FIG. 1.

In FIG. 3, the light source drive circuit 1 includes the coarse delay circuit 10 and the fine delay circuit 20. The fine delay circuit 20 includes a phase changing circuit 200 and an FF circuit 201 by a D-FF (flip-flop) circuit. Note that, in FIG. 3, the LD driver 40 to which the output signal out of the light source drive circuit 1 is supplied and the LD 41 driven by the LD driver 40 to emit light are omitted.

In the light source drive circuit 1, for example, the signal Sig, which is a PWM signal having a predetermined cycle, is input to the coarse delay circuit 10 as an input signal.

The light source drive circuit 1 further includes the phase comparison circuit 30 that compares a phase of the signal Sig input to the light source drive circuit 1 and a phase of the output signal out output from the fine delay circuit 20. The phase comparison circuit 30 generates, based on a comparison result of the phases of the signal Sig and the output signal out, a coarse control signal for controlling a delay by the coarse delay circuit 10 and a fine control signal for controlling a delay by the fine delay circuit 20. The coarse control signal is supplied to the coarse delay circuit 10. Further, the fine control signal is supplied to the phase changing circuit 200 included in the fine delay circuit 20.

According to control by the coarse control signal supplied from the phase comparison circuit 30, the coarse delay circuit 10 gives, to the input signal Sig, a delay of a delay amount corresponding to the cycle of the clock signal CLK and outputs the signal Sig as the signal SigCd. At this time, the coarse delay circuit 10 can apply a configuration capable of outputting the signal SigCd with a phase of the signal SigCd shifted in units of 90° according to the control of the coarse control signal.

In the fine delay circuit 20, the fine control signal explained above is input to the phase changing circuit 200 and the clock signal CLK is input to the phase changing circuit 200. The phase changing circuit 200 delays the input clock signal CLK by a delay amount of time resolution smaller than the cycle of the clock signal CLK and outputs the clock signal CLK according to control by the fine control signal. More specifically, the phase changing circuit 200 delays the signal SigCd by a delay amount corresponding to any phase angle at least in a range of a phase angle of 0° to 90° and outputs the signal SigCd.

The clock signal CLK delayed by the phase changing circuit 200 is input to a clock input end of the FF circuit 201. The signal SigCd output from the coarse delay circuit 10 is input to a data input end of the FF circuit 201. The FF circuit 201 outputs signal SigCd, which is input to the data input end, in synchronization with the clock signal CLK delayed by the phase changing circuit 200. That is, the fine delay circuit 20 delays, according to a delay amount by the phase changing circuit 200, the signal SigCd supplied from the coarse delay circuit 10 and outputs the signal SigCd as the output signal out. Here, the FF circuit 201 functions as a synchronization circuit that synchronizes the signal SigCd output from the coarse delay circuit 10 with the signal delayed by the fine delay circuit 20.

In the fine delay circuit 20, the output of the FF circuit 201 is output from the light source drive circuit 1 as the output signal out by the fine delay circuit 20.

As explained above, the light source drive circuit 1 according to the first embodiment gives, with the coarse delay circuit 10, a delay in units of the cycle of the clock signal CLK to the input signal Sig and further gives, with the fine delay circuit 20, a delay to the output of the coarse delay circuit 10 with time resolution smaller than the cycle of the clock signal CLK. The light source drive circuit 1 drives the LD 41 according to the output signal out output from the fine delay circuit 20.

Therefore, by applying the light source drive circuit 1 according to the present disclosure, it is possible to control light emission timing of the LDs 41 with higher accuracy using a relatively small-scale circuit configuration.

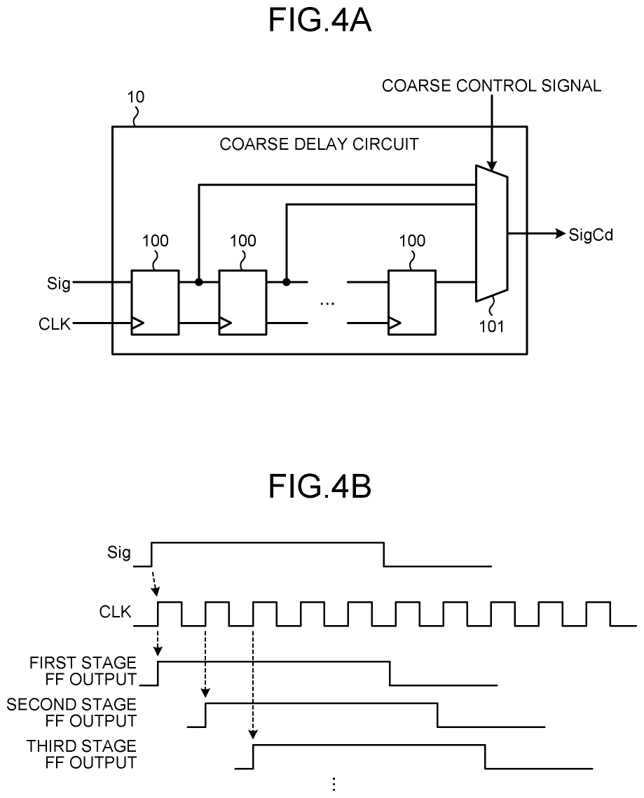

FIG. 4A is a diagram illustrating a configuration of an example of the coarse delay circuit 10 applicable to the first embodiment. In FIG. 4A, the coarse delay circuit 10 includes a plurality of FF circuits 100 connected in series and a selector 101 including a plurality of input ends. The clock signal CLK is input to clock input ends of the FF circuits 100. The FF circuits 100 respectively give a delay corresponding to the cycle of the clock signal CLK to the input signals. That is, the signal Sig is input to a data input end of the FF circuit 100 in a first stage (an input stage) among the plurality of FF circuits 100.

FIG. 4B is an exemplary sequence chart for explaining an operation of the coarse delay circuit 10 applicable to the first embodiment. FIG. 4B illustrates the signal Sig, the clock signal CLK, an output of the FF circuit 100 in the first stage, an output of the FF circuit 100 in a second stage, an output of the FF circuit 100 in a third stage, and the like respectively from the top. The signal Sig may have no relationship with the clock signal CLK. Rising timing and a maintaining period (cycle) in a high (High) state may be different from those of the clock signal CLK.

The signal Sig is latched by the FF circuit 100 in the first stage and is output with the rising timing synchronized with the rising timing of the clock signal CLK. The signal Sig output from the FF circuit 100 in the first stage in synchronization with the clock signal CLK is input to the FF circuit 100 in the second stage and delayed by one cycle of the clock signal CLK. The signal Sig delayed by the FF circuit 100 in the second stage is input to the FF circuit 100 (not illustrated) in the third stage and is delayed by one cycle of the clock signal CLK. That is, an output of the FF circuit 100 in the third stage is a signal delayed by two cycles of the clock signal CLK with respect to the output of the FF circuit 100 in the first stage. This operation is repeated up to the FF circuit 100 immediately before the selector 101. When the coarse delay circuit 10 includes n (n>1) FF circuits 100, an output of the FF circuit 100 immediately before the selector 101 is a signal delayed by a (n−1) cycle of the clock signal CLK with respect to an output of the FF circuit 100 in an n-th stage.

In the selector 101, outputs of the FF circuits 100 are input to the plurality of input ends. According to a coarse control signal, the selector 101 selects one from signals input to the plurality of input ends and outputs the selected signal from the coarse delay circuit 10 as the signal SigCd. The signal SigCd is a signal in which the signal Sig is synchronized with the clock signal CLK and further delayed by any delay amount of one cycle, two cycles, . . . , or (n−1) cycles of the clock signal CLK according to the coarse control signal.

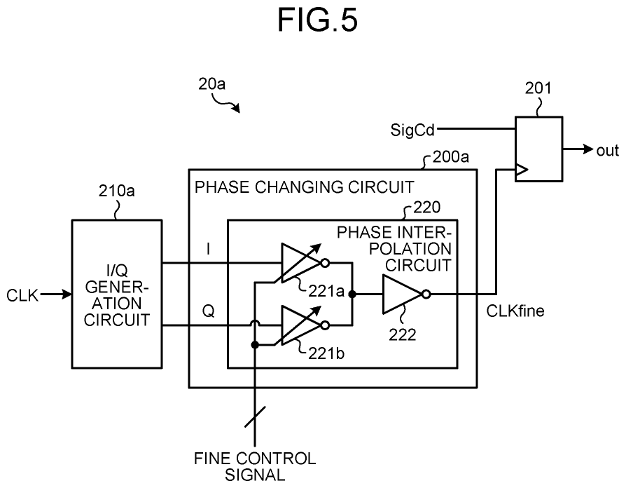

FIG. 5 is a diagram illustrating a configuration of an example of the fine delay circuit 20 applicable to the first embodiment. In FIG. 5, the fine delay circuit 20a includes a phase changing circuit 200a and the FF circuit 201. In the FF circuit 201, the signal SigCd supplied from the coarse delay circuit 10 is input to the data input end and a signal CLKfine output from the phase changing circuit 200a is input to the clock input end.

The phase changing circuit 200a includes a phase interpolation circuit 220. The phase interpolation circuit 220 includes inverter circuits 221a and 221b and an inverter circuit 222 to which a signal obtained by combining outputs of the inverter circuits 221a and 221b is input.

In FIG. 5, the fine delay circuit 20 further includes an I/Q generation circuit 210a. The I/Q generation circuit 210a generates, based on the clock signal CLK, a clock signal I, which is an I-phase (In Phase) clock signal, and a clock signal Q, which is a Q-phase (Quadrature Phase) clock signal having a phase different from the I-phase by 90°. As an example, when a frequency of the clock signal CLK is 5 [GHz (gigahertz)], frequencies of the clock signals I and Q are respectively 2.5 [GHz]. The I/Q generation circuit 210a supplies the generated clock signals I and Q respectively to the inverter circuits 221a and 221b.

The phase interpolation circuit 220 can set a phase of a signal obtained by combining outputs of the inverter circuits 221a and 221b to any phase in a range of 0° to 90° by gains of the respective inverter circuits 221a and 221b being complementarily controlled by the fine control signal. That is, the phase interpolation circuit 220 interpolates the phase in the range of 0° to 90° according to the fine control signal.

For example, by setting a gain to 100% for the inverter circuit 221a and setting a gain to 0% for the inverter circuit 221b, the signal obtained by combining the outputs of the inverter circuits 221a and 221b is changed to a signal in the same phase as the clock signal I. By setting a gain to 0% for the inverter circuit 221a and setting a gain to 100% for the inverter circuit 221b, the signal obtained by combining the outputs of the inverter circuits 221a and 221b is changed to a signal in the same phase as the clock signal Q. Further, for example, by setting a gain to 50% respectively for the inverter circuits 221a and 221b, the signal obtained by combining the outputs of the inverter circuits 221a and 221b is changed to a signal, a phase of which is shifted by 45° with respect to the clock signal I.

The signal obtained by combining the outputs of the inverter circuits 221a and 221b is input to the inverter circuit 222 and output from the inverter circuit 222 as the signal CLKfine. As explained above, the signal CLKfine is a signal, a phase of which is controlled in the range of 0° to 90° according to the fine control signal, and is a signal obtained by giving a delay corresponding to the phase to the clock signal CLK. In this way, the phase changing circuit 200a can give a delay shorter than the cycle of the clock signal CLK to the clock signal CLK and output the clock signal CLK.

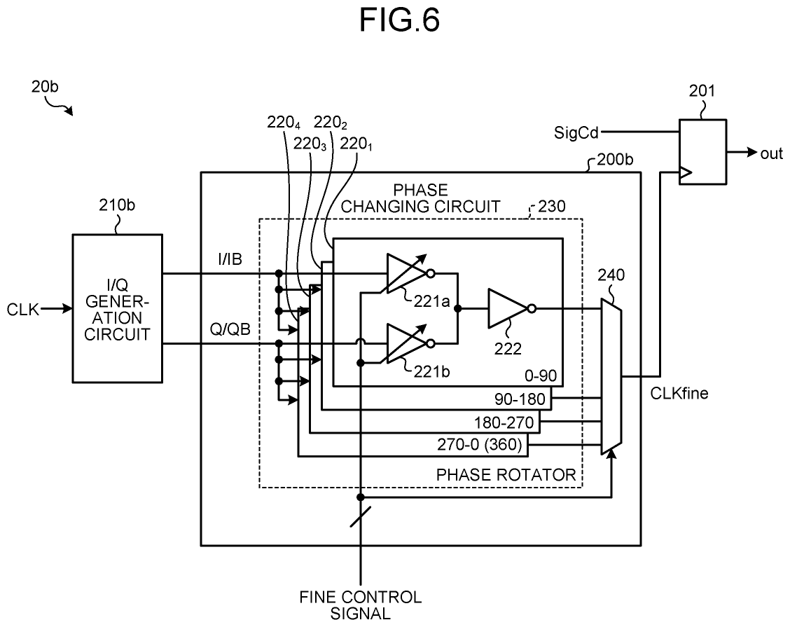

FIG. 6 is a diagram illustrating a configuration of another example of the fine delay circuit 20 applicable to the first embodiment. In FIG. 6, the fine delay circuit 20b includes a phase changing circuit 200b and the FF circuit 201. In the FF circuit 201, the signal SigCd supplied from the coarse delay circuit 10 is input to the data input end and the signal CLKfine output from the phase changing circuit 200b is input to the clock input end.

The phase changing circuit 200b includes a phase rotator 230 and a selector 240. The phase rotator 230 includes four phase interpolation circuits 220₁, 220₂, 220₃, and 220₄ that respectively interpolate phases in different ranges at every 90°. Each of the phase interpolation circuits 220₁ to 220₄ includes two inverter circuits 221a and 221b, gains of which are complementarily controlled according to a fine control signal, and an inverter circuit 222 to which a signal obtained by combining outputs of the inverter circuits 221a and 221b is input.

In FIG. 6, the fine delay circuit 20b further includes an I/Q generation circuit 210b. Based on the clock signal CLK, the I/Q generation circuit 210b generates the clock signal I, which is an I-phase clock signal, and a clock signal Q, which is a Q-phase clock signal. Further, the I/Q generation circuit 210b generates a clock signal IB, a phase of which is different from that of the clock signal I by 180°, and a clock signal QB, a phase of which is different from that of the clock signal Q by 180°. As an example, when a frequency of the clock signal CLK is 5 [GHz], frequencies of the clock signals I, Q, IB, and QB are respectively 2.5 [GHz].

For example, the clock signals I and Q are respectively supplied to the respective inverter circuits 221a and 221b of the phase interpolation circuit 2201. The clock signals Q and IB are respectively supplied to the inverter circuits 221a and 221b of the phase interpolation circuit 2202. The clock signals IB and QB are respectively supplied to the inverter circuits 221a and 221b of the phase interpolation circuit 2203. The clock signals QB and I are respectively supplied to the inverter circuits 221a and 221b of the phase interpolation circuit 2204.

Each of the phase interpolation circuits 2201 to 220₄ can set a phase of the signal obtained by combining the outputs of the inverter circuits 221a and 221b to respectively any phases in ranges of 0° to 90°, 90° to 180°, 180° to 270°, and 270° to 360° because the gains of the inverter circuits 221a and 221b are complementarily controlled by the fine control signal. In this way, the phase rotator 230 can rotate the phase of the output signal by 0° to 360° according to the fine control signal.

The outputs of the respective phase interpolation circuit 220₁ to 220₄ are input to the selector 240. The selector 240 selects one from the outputs of the phase interpolation circuits 220₁ to 220₄ according to the control of the fine control signal and outputs the selected one output as the signal CLKfine.

As explained above, the signal CLKfine is a signal, a phase of which is controlled in a range of 0° to 360° according to the fine control signal, and is a signal obtained by giving a delay corresponding to the phase to the clock signal CLK. In this way, the phase changing circuit 200b can give a delay shorter than the cycle of the clock signal CLK to the clock signal CLK and output the clock signal CLK.

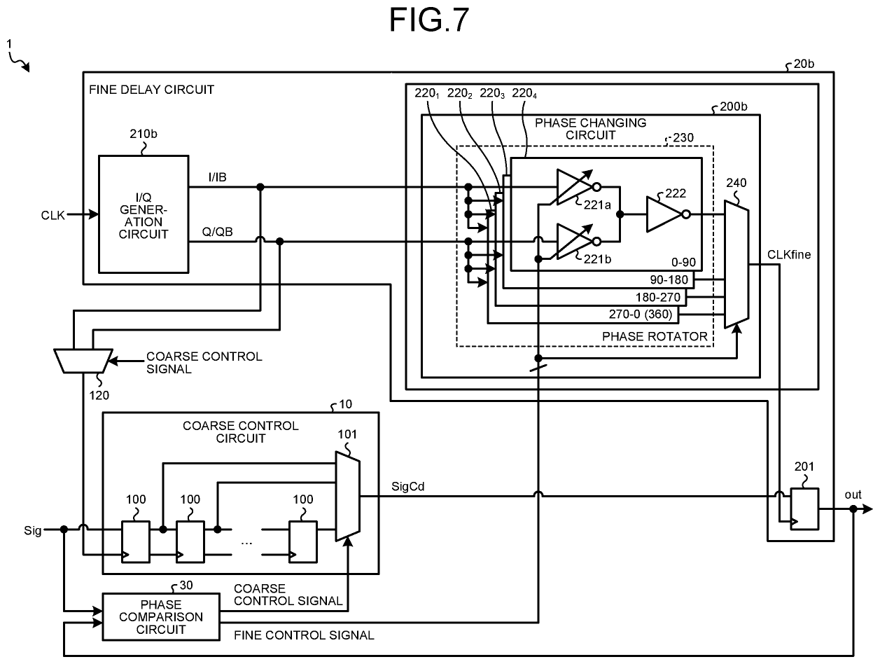

FIG. 7 is a diagram more specifically illustrating a configuration of an example of the light source drive circuit 1 according to the first embodiment. Note that, in the example illustrated in FIG. 7, the fine delay circuit 20b including the phase changing circuit 200b explained with reference to FIG. 6 is applied as the fine delay circuit 20. Note that, in FIG. 7, detailed explanation is omitted concerning portions common to the portions explained with respect to the figures explained above.

In FIG. 7, the signal SigCd output from the coarse delay circuit 10 is input to the data input end of the FF circuit 201 included in the fine delay circuit 20b. The FF circuit 201 synchronizes the signal SigCd input to the data input end with the signal CLKfine, which is the output of the phase changing circuit 200b, input to the clock input end of the FF circuit 201 and outputs the signal SigCd as the output signal out.

On the other hand, the four clock signals I, Q, IB, and QB generated by the I/Q generation circuit 210b are supplied to a selector 120. The selector 120 selects and outputs any one of the four clock signals I, Q, IB, and QB according to the coarse control signal. The clock signal output from the selector 120 is input to the coarse delay circuit 10 as the clock signal CLK.

The selector 120 selects a signal, a phase of which is not advanced with respect to the signal CLKfine output from the fine delay circuit 20b, from the four clock signals I, Q, IB, and QB according to the coarse control signal. This is because the coarse delay circuit 10 preferably outputs the signal SigCd at timing that can be synchronized by the FF circuit 201 in the fine delay circuit 20b.

As an example, a case is conceived in which the clock signal IB is selected in the selector 120, the coarse delay circuit 10 outputs the signal SigCd obtained by shifting the phase of the signal Sig by 180°, and the phase changing circuit 200b of the fine delay circuit 20b outputs the signal CLKfine with the phase of 90°. This is because, in this case, the FF circuit 201 synchronizes the signal SigCd with the signal CLKfine, a phase of which is advanced by 90° with respect to the signal SigCd output from the coarse delay circuit 10, and it is likely that the signal SigCd is not synchronized at timing when the signal SigCd is originally desired to be synchronized.

(3-0-2. Operation According to the First Embodiment)

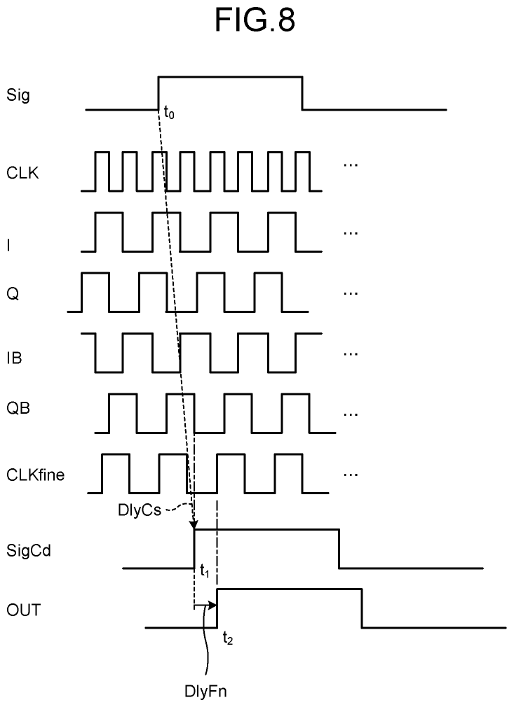

Next, an example of an operation of the light source drive circuit 1 according to the first embodiment is explained. FIG. 8 is a sequence chart illustrating the example of the operation of the light source drive circuit 1 according to the first embodiment. Note that, in the example illustrated in FIG. 8, the configuration including the phase rotator 230 illustrated in FIG. 7 is applied to the light source drive circuit 1. In FIG. 8, the signal Sig, the clock signal CLK, the clock signal I, the clock signal Q, the clock signal IB, the clock signal QB, the signal CLKfine, the signal SigCd, and the output signal out are respectively illustrated in order from the top. Here, in the following explanation, it is assumed that the clock signal I and the clock signal QB are used among the clock signals I, Q, IB, and QB output from the I/Q generation circuit 210b.

The clock signal I is a signal in the same phase as the clock signal CLK, rising of the signal being synchronized with rising of the clock signal CLK. On the other hand, the clock signal QB is a signal, a phase of which is shifted by 90° from the clock signal CLK, rising of the signal being synchronized with falling of the clock signal CLK. The clock signals I and QB respectively have cycles twice as large as the cycle of the clock signal CLK.

In this example, the fine delay circuit 20b uses the phase rotation circuit 2211 according to the fine control signal and generates a signal, a phase of which is advanced by 45° with respect to the clock signal CLK and a cycle of which is twice as large as the cycle of the clock signal CLK, based on the clock signals I and QB. In the fine delay circuit 20b, the phase changing circuit 200b outputs this signal as the signal CLKfine.

On the other hand, the selector 120 selects the clock signal QB according to a coarse control signal corresponding to the fine control signal explained above. The selected clock signal QB is input to the coarse delay circuit 10 as the clock signal CLK. The coarse delay circuit 10 delays the input signal Sig to time t₁ of the next falling timing of the clock signal CLK (the clock signal QB) (a delay time DlyCs) with respect to time to of the rising timing of the signal Sig and outputs the signal Sig as the signal SigCd.

The signal SigCd is input to the data input end of the FF circuit 201 of the fine delay circuit 20b. The FF circuit 201 outputs the input signal SigCd at time t₂ of falling timing of the signal CLKfine input to the clock input end. That is, the signal SigCd is output by the FF circuit 201 as a signal that rises at time t₂ delayed from time t₁ by a delay time Dlyfn that is a difference between time t₁ and time t₂. The delay time Dlyfn is a signal, a phase of which is delayed by 45° with respect to the clock signal CLK.

As explained above, the light source drive circuit 1 according to the first embodiment can take in the input signal Sig according to the clock signal CLK, thereafter give a delay of a cycle shorter than the cycle of the clock signal CLK to the signal Sig, and output the signal Sig as the output signal out.

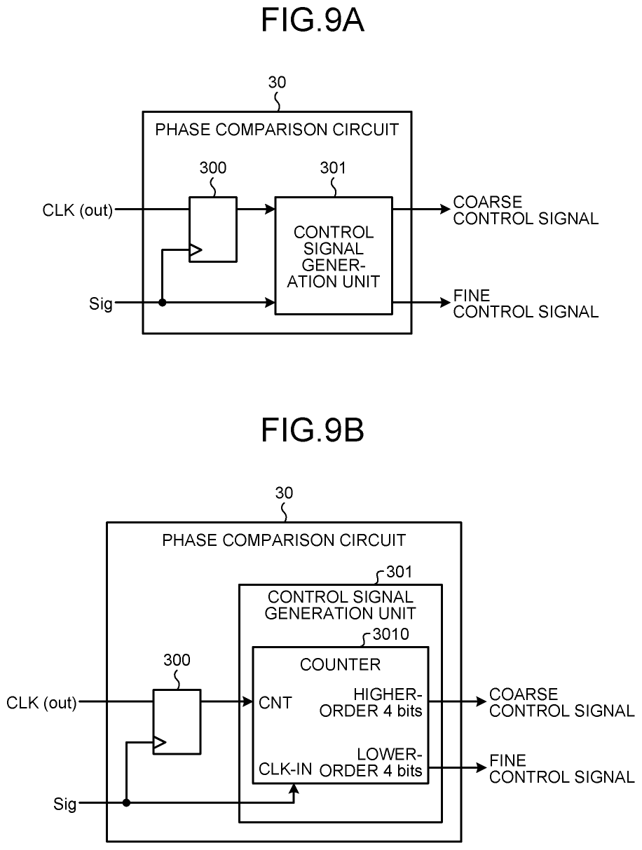

Next, the phase comparison circuit 30 applicable to the first embodiment is more specifically explained. FIG. 9A is a block diagram illustrating a schematic configuration example of the phase comparison circuit 30 according to the first embodiment.

In FIG. 9A, the phase comparison circuit 30 includes an FF circuit 300 and a control signal generation unit 301. The output signal out is input to a data input end of the FF circuit 300. An output of the FF circuit 300 is input to one input end of the control signal generation unit 301. The signal Sig is input to a clock input end of the FF circuit and the other input end of the control signal generation unit 301. The control signal generation unit 301 outputs a coarse control signal and a fine control signal at timing based on the signals input to one and the other input ends.

FIG. 9B is a block diagram illustrating a more specific configuration example of the phase comparison circuit 30 applicable to the first embodiment. As illustrated in FIG. 9B, the control signal generation unit 301 includes a counter 3010 that performs counting according to the output of the FF circuit 300. The control signal generation unit 301 outputs the coarse control signal and the fine control signal at timing based on a count value by the counter 3010.

In FIG. 9B, the counter 3010 is, for example, an 8-bit counter that counts 8 bits, the signal Sig is input to an input end CLK-IN, and the output of the FF circuit 300 is input to an input end CNT. The counter 3010 counts a signal input to the input end CNT according to the signal Sig input to the input end CLK-IN. The counter 3010 outputs higher-order 4 bits of an 8-bit count value as the coarse control signal and outputs lower-order 4 bits as the fine control signal.

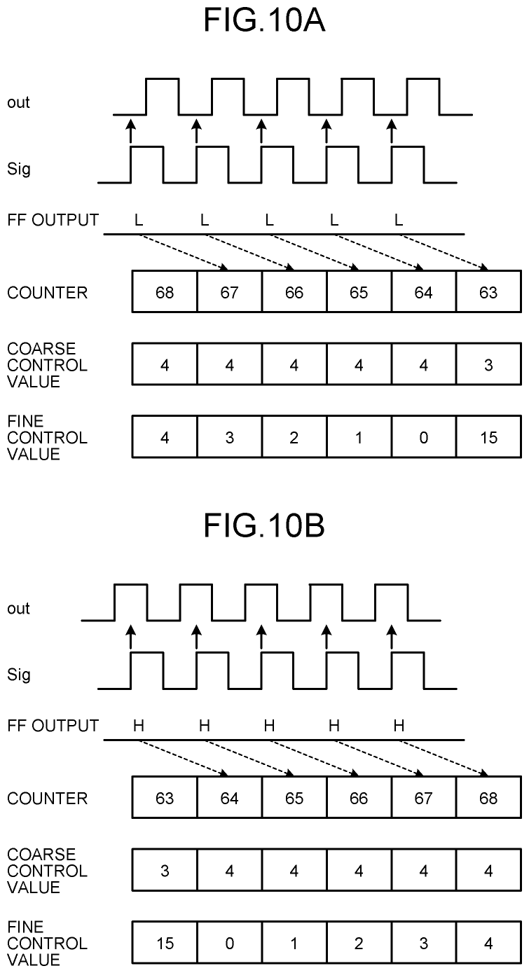

FIG. 10A and FIG. 10B are sequence charts for explaining an example of an operation of the phase comparison circuit 30 according to the first embodiment. In FIG. 10A and FIG. 10B, the output signal out, the signal Sig, the output (FF output) of the FF circuit 300, a count value of the counter, a coarse control value, and a fine control value are respectively illustrated from the top.

FIG. 10A illustrates an example in which a phase of the output signal out is delayed with respect to a phase of the signal Sig. The FF circuit 300 takes in the output signal out at timing of a rising edge of the signal Sig. Since the signal Sig and the output signal out have the same cycle, the output of the FF circuit 300 changes to a low (L) state as illustrated as an FF output in FIG. 10A. Specifically, when acquiring the low state of the output signal out at the timing of the rising edge of the signal Sig, the FF circuit 300 outputs the low state at the next rising edge.

In the control signal generation unit 301, the counter 3010 decrements the count value by 1 according to the output of the FF circuit 300 in the low state at the timing of the rising edge of the signal Sig. In this example, since the counter 3010 is the 8-bit counter, as illustrated in FIG. 10A, a count value started with a value “68” in the figure is decremented by 1 for each rising edge of the signal Sig to a value “67”, a value “66”, and the like.

FIG. 10B illustrates an example in which the phase of the output signal out advances with respect to the phase of the signal Sig. In this case, the output of the FF circuit 300 changes to a high (H) state as illustrated as an FF output in FIG. 10B. Specifically, when acquiring the high state of the output signal out at the timing of the rising edge of the signal Sig, the FF circuit 300 outputs the high state at the next rising edge.

The counter 3010 increments the count value by 1 according to the output of the FF circuit 300 in the high state at the timing of the rising edge of the signal Sig. In this example in which the counter 3010 is the 8-bit counter, as illustrated in FIG. 10B, a count value started with a value “63” in the figure is incremented by 1 for each rising edge of the signal Sig to a value “64”, a value “65”, and the like.

In the control signal generation unit 301, the counter 3010 uses a value of lower-order m bits (m<n) of a count value by the n-bit counter as a fine control value for a fine control signal and uses a value of higher-order (n-m) bits of the counter as a coarse control value for a coarse control signal. More specifically, in this example in which the counter 3010 is the 8-bit counter, the counter 3010 outputs higher-order 4 bits of the 8-bit count value as the coarse control value. The counter 3010 outputs lower-order 4 bits of the 8-bit counter value as the fine control value.

In the example illustrated in FIG. 10A in which the phase of the output signal out is delayed with respect to the phase of the signal Sig, the counter 3010 outputs the coarse control value as a value “4”, a value “4”, a value “4”, a value “4”, a value “4”, a value “3”, and the like and outputs the fine control value as a value “4”, a value “3”, a value “2”, a value “1”, a value “0”, a value “15”, and the like according to the rising of the signal Sig. On the other hand, in the example illustrated in FIG. 10B in which the phase of the output signal out advances with respect to the phase of the signal Sig, the counter 3010 outputs the coarse control value as a value “3”, a value “4”, a value “4”, a value “4”, a value “4”, a value “4”, and the like and outputs the fine control value as a value “15”, a value “0”, a value “1”, a value “2”, a value “3”, a value “4”, and the like according to the rising of the signal Sig.

The phase comparison circuit 30 supplies a coarse control signal indicating a coarse control value to the coarse delay circuit 10. In the coarse delay circuit 10, the selector 101 selects, according to the coarse control value indicated by the coarse control signal, for example, an output of the FF circuit 100 indicated by the coarse control value among the plurality of FF circuits 100.

More specifically, for example, if the coarse control value is a value “3”, the coarse delay circuit 10 selects an output of the FF circuit 100 in the third stage with the selector 101 and outputs the signal Sig synchronizing with the clock signal CLK as the signal SigCd delayed by three cycles of the clock signal CLK. Similarly, for example, when the coarse control value is a value “4”, the coarse delay circuit 10 selects an output of the FF circuit 100 of the fourth stage with the selector 101 and outputs the signal Sig synchronizing with the clock signal CLK as the signal SigCd delayed by four cycles of the clock signal CLK. Output as the signal SigCd.

The phase comparison circuit 30 supplies a fine control signal indicating a fine control value to the fine delay circuit 20. The fine delay circuit 20 gives a delay within one cycle of the clock signal CLK with the phase changing circuit 200 according to the fine control value indicated by the fine control signal. In this example in which the fine control value is a 4-bit value, the fine delay circuit 20 gives a delay to the signal SigCd in units obtained by dividing one cycle of the clock signal CLK by 16 (=2⁴) with the phase changing circuit 200.

More specifically, if the fine control value is a value “1”, the fine delay circuit 20 gives a delay for a ( 1/16) cycle of the clock signal CLK to the signal SigCd. Similarly, if the fine control value is a value “3”, the fine delay circuit 20 gives a delay for a ( 3/16) cycle of the clock signal CLK to the signal SigCd.

The phase comparison circuit 30 compares a phase of the output signal out output from the fine delay circuit 20 and a phase of the signal Sig input to the light source drive circuit 1 and generates a coarse control value and a fine control value as explained with reference to FIG. 10A and FIG. 10B.

The fine control value is updated every time the signal Sig rises, whereby the phase of the output signal out is delayed in units of a ( 1/16) cycle of the clock signal CLK. For example, it is assumed that the phase of the output signal out is delayed with respect to the phase of the signal Sig and the fine control value is decremented and changes to, for example, a value “5”, a value “4”, a value “3”, and a value “2”. In this case, a delay amount of the output signal out decreases by a ( 5/16) cycle, a ( 4/16) cycle, a ( 3/16) cycle, and the like of the clock signal CLK within one cycle of the clock signal CLK.

For example, when the fine control value changes to the value “5”, the value “4”, the value “3”, and the value “2”, if the phase of the output signal out coincides the phase of the signal Sig between the value “3” and the value “2”, the output of the FF circuit 300 transitions from a low (L) state to a high (H) state at timing of the value “2”. Therefore, the phase comparison circuit 30 starts to increment the fine control value from a point in time when the output of the FF circuit 300 transitions from the low (L) state to the high (H) state.

The phase comparison circuit 30 performs phase matching between the signal Sig and the output signal out by repeating the decrement and the increment of the fine control value in this way. Here, when the phase of the output signal out coincides with the phase of the signal Sig, the counting operation by the counter 3010 stops. In this state, the phase comparison circuit 30 samples a rising edge of the output signal out, increments and decrements the fine control value based on a sampling result, and stabilizes the output signal out.

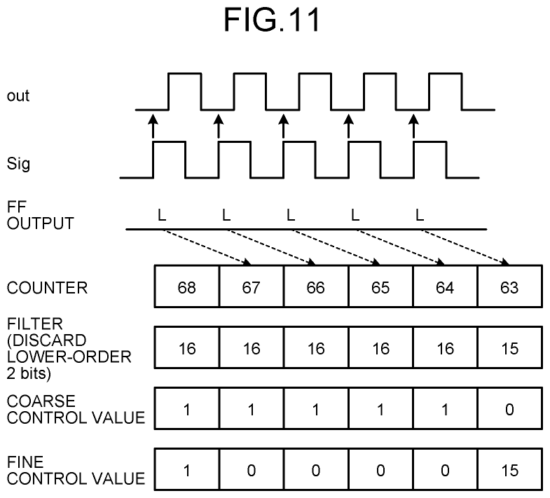

FIG. 11 is a sequence chart for explaining another example of the operation of the phase comparison circuit 30 according to the first embodiment. In FIG. 11, the output signal out, the signals Sig, an FF output, a count value of the counter, a filter processing value, a coarse control value, and a fine control value are illustrated from the top.

In another example of the operation of the phase comparison circuit 30, for example, filter processing for using only higher-order k bits (k<n), that is, discarding lower-order (n−k) bits is applied to an n-bit counter value and output timings for the coarse control signal and the fine control signal are determined based on the filter processing value after the filter processing.

In the example illustrated in FIG. 11, the control signal generation unit 301 performs filtering processing for discarding lower-order 2 bits of an 8-bit counter value in the counter 3010. The control signal generation unit 301 uses a value of lower-order 4 bits of a 6-bit filter processing value after the filter processing as a fine control value and uses a value of higher-order 2 bits of the filter processing value as a coarse control value. That is, the fine control value is a value decremented by “1” at every four cycles of the signal Sig. On the other hand, the coarse control value is a value decremented by “1” at every 16 cycles of the signal Sig.

As explained above, in the other example of the operation of the phase comparison circuit 30, an update interval for the coarse control signal and the fine control signal is longer compared with an update interval in the operation example explained with reference to FIG. 10A and FIG. 10B. Therefore, in the other example of the operation of the phase comparison circuit 30, sensitivity of control for the phase comparison result of the signal Sig and the output signal out in the phase comparison circuit 30 can be set lower compared with the operation example explained with reference to FIG. 10.

(3-1. First Modification of the First Embodiment)

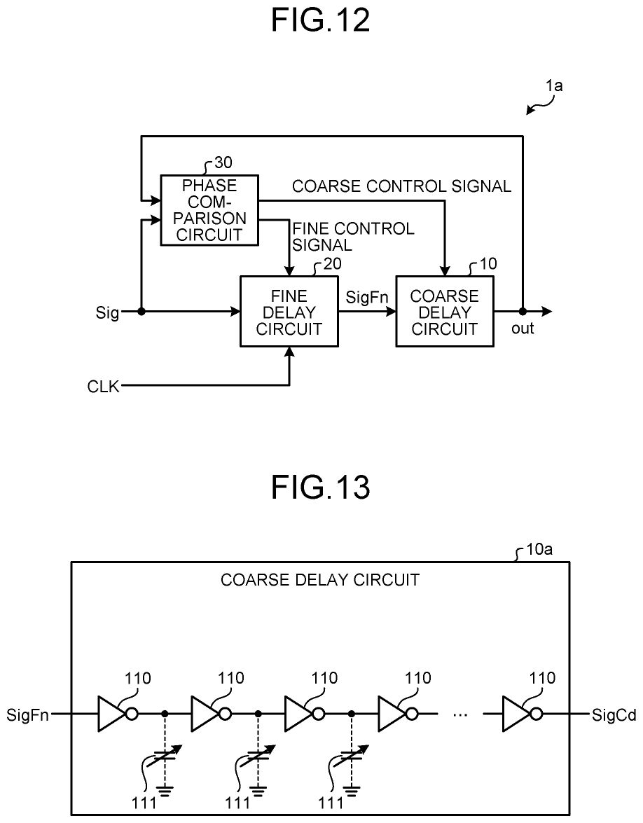

Next, a first modification of the first embodiment of the present disclosure is explained. FIG. 12 is a block diagram illustrating a configuration of an example of a light source drive circuit according to the first modification of the first embodiment. In FIG. 12, the LD driver 40 to which the output signal out of a light source drive circuit 1a is supplied and the LD 41 driven by the LD driver 40 to emit light are omitted.

In FIG. 12, the light source drive circuit 1a includes the coarse delay circuit 10, the fine delay circuit 20, and the phase comparison circuit 30 like the light source drive circuit 1 in the first embodiment explained above. Here, in the light source drive circuit 1a according to the first modification of the first embodiment, the signal Sig is input to the fine delay circuit 20 and an output of the fine delay circuit 20 is input to the coarse delay circuit 10. The coarse delay circuit 10 delays an input signal according to a coarse control signal and outputs the signal as the output signal out.

As in the first embodiment, the fine delay circuit 20 delays the input signal Sig with a delay amount of time resolution smaller than the cycle of the clock signal CLK according to control by the fine control signal and outputs the signal Sig as the signal SigFn. For example, the fine delay circuit 20 delays the signal SigCd with a delay amount corresponding to any phase angle at least in a range of a phase angle of 0° to 90°.

The signal SigFn output from the fine delay circuit 20 is input to the coarse delay circuit 10. The coarse delay circuit 10 delays the input signal SigFn according to the control by the coarse control signal and outputs the signal SigFn as the output signal out. At this time, the coarse delay circuit 10 gives a delay to the input signal SigFn based on a cycle of the signal SigFn (that is, a cycle of the signal Sig) and outputs the signal SigFn as the output signal out.

(3-1-1. First Example of the First Modification of the First Embodiment)

FIG. 13 is a diagram illustrating a first example of the coarse delay circuit 10 applicable to the first modification of the first embodiment. In FIG. 13, the coarse delay circuit 10a includes a plurality of inverter circuits 110 connected in series and a plurality of variable capacitors 111, one ends of which are connected to connection points to which the inverter circuits 110 are connected.

The inverter circuits 110 delay the input signal SigFn according to a cycle of the signal SigFn. A waveform of a signal output from the inverter circuit 110 is blunted by the variable capacitor 111. The signal having the blunted waveform is input to the inverter circuit 110 in the next stage. In the inverter circuit 110 in the next stage, since the waveform of the input signal is blunted, signal inversion timing is delayed and the signal is delayed and output. At this time, a delay amount (a phase shift amount) of the signal SigCd with respect to the signal SigFn can be changed by changing the capacitances of the variable capacitors 111 according to, for example, a coarse control signal.

As explained above, the light source drive circuit 1a can delay the input signal Sig by a delay amount of the time resolution smaller than the cycle of the clock signal CLK and further delay the input signal Sig by a delay amount corresponding to the cycle of the signal Sig.

(3-1-2. Second Example of the First Modification of the First Embodiment)

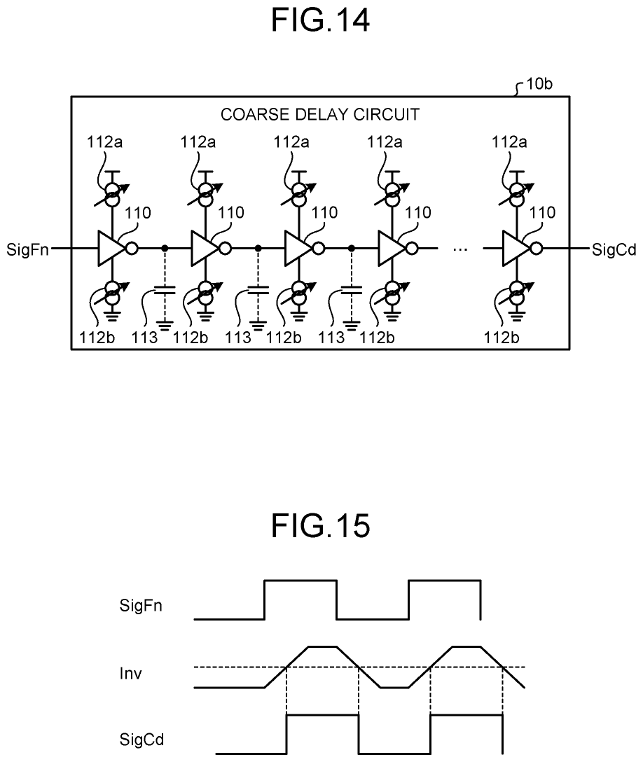

FIG. 14 is a diagram illustrating a second example of the coarse delay circuit 10 applicable to the first modification of the first embodiment. In FIG. 14, the coarse delay circuit 10b includes a plurality of inverter circuits 110 connected in series and a plurality of capacitors 113, one ends of which are connected to connection points to which the inverter circuits 110 are connected.

In the inverter circuits 110, current limiting circuits 112a and 112b are respectively provided on a power supply side and a ground side. The current limiting circuits 112a and 112b limit, for example, a current value of a power supply for the inverter circuits 110 to operate to a value smaller than a current value at which an optimum operation can be performed in the inverter circuits 110. Note that, in the example illustrated in FIG. 14, the current limiting circuits 112a and 112b are provided on each of the power supply side and the ground side of the inverter circuits 110. However, this is not limited to this example. Only one of the current limiting circuits 112a and 112b may be provided with respect to the inverter circuit 110.

FIG. 15 is a schematic diagram for explaining an operation according to the second example of the coarse delay circuit 10 applicable to the first modification of the first embodiment illustrated in FIG. 14. The signal Sig by a rectangular wave is a signal Inv in which an original waveform of the signal Sig is blunted by the inverter circuits 110 respectively subjected to current limitation and the plurality of capacitors 113. This signal Inv is shaped by the inverter circuit 110 in the last stage and is output as the signal SigCd by a rectangular wave, a phase of which is shifted with respect to the signal Sig. At this time, by controlling an electric current supplied to the inverter circuits 110 with the current limiting circuits 112a and 112b according to a coarse control signal, it is possible to change a delay amount (a phase shift amount) of the signal SigCd with respect to the signal SigFn.

(3-1-3. Third Example of the First Modification of the First Embodiment)

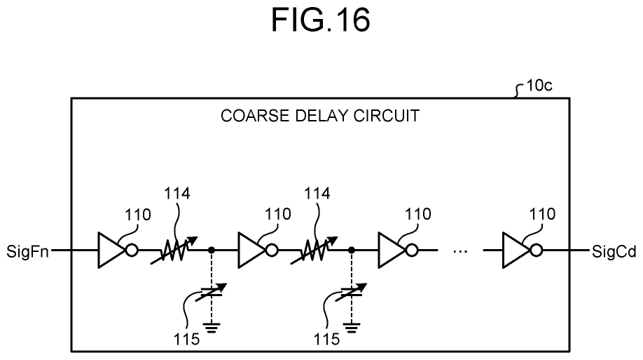

FIG. 16 is a diagram illustrating a third example of the coarse delay circuit 10 applicable to the first modification of the first embodiment. In FIG. 16, a coarse delay circuit 10c is an example in which filter circuits (RC circuits) including variable resistors 114 and variable capacitors 115 are inserted among a plurality of inverter circuits 110 connected in series. In a configuration illustrated in FIG. 16, a signal output from the inverter circuits 110 is delayed according to a time constant by the variable resistors 114 and the variable capacitors 115 in the filter circuit and is input to the inverter circuit 110 in the next stage. The delay amount (a phase shift amount) of the signal SigCd with respect to the signal SigFn can be changed by controlling values of the variable resistors 114 and the variable capacitors 115 according to a coarse control signal.

(3-2. Second Modification of the First Embodiment of the Present Disclosure)

Next, a second modification of the first embodiment of the present disclosure is explained. The second modification of the first embodiment is an example of a light source drive circuit including a configuration in which the output signal out obtained by the input signal Sig being delayed by the coarse delay circuit 10 and the fine delay circuit 20 is supplied to the LD driver 40 to drive the LD 41 and a configuration by a replica of the configuration.

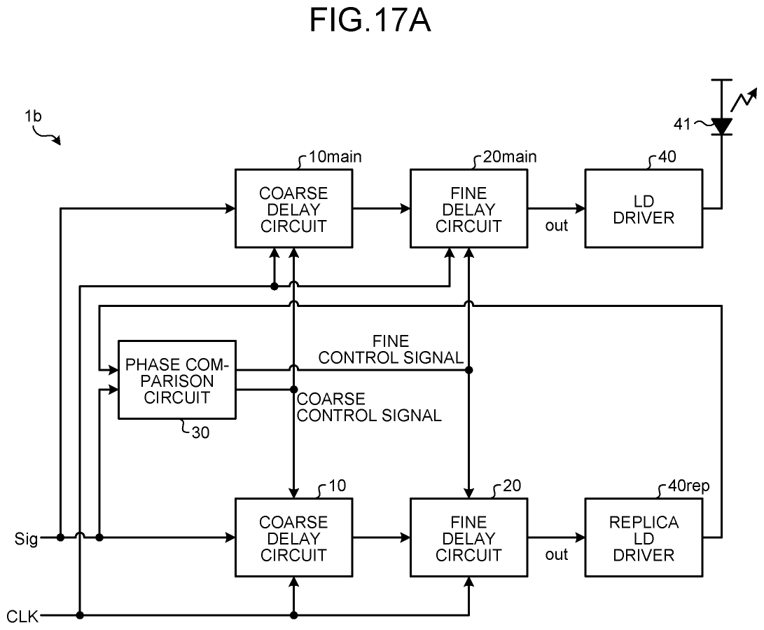

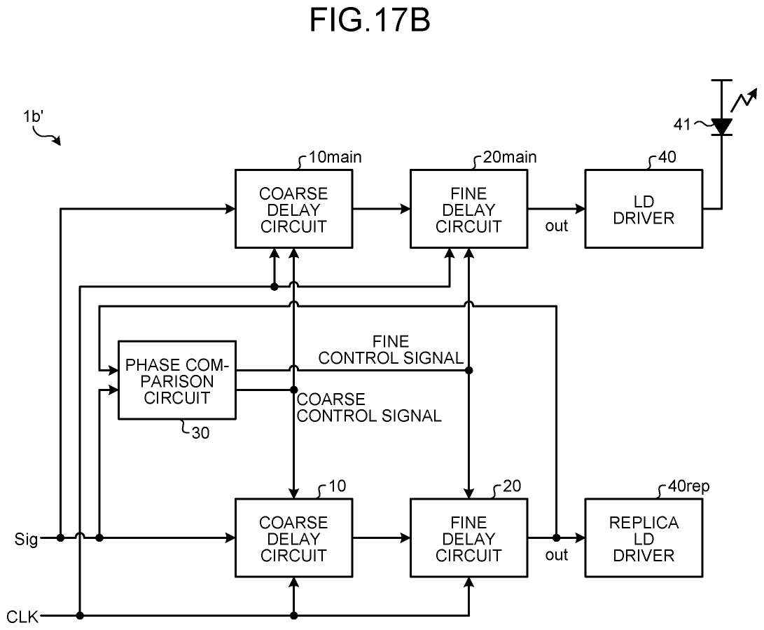

FIG. 17A is a block diagram illustrating a configuration of an example of a light source drive circuit according to the second modification of the first embodiment. In FIG. 17A, the light source drive circuit 1b includes the coarse delay circuit 10, the fine delay circuit 20, and the phase comparison circuit 30 and also includes a coarse delay circuit 10main (a third delay circuit) and a fine delay circuit 20main (a fourth delay circuit). The coarse delay circuit 10main has the same configuration as the coarse delay circuit 10. Similarly, the fine delay circuit 20main has the same configuration as the fine delay circuit 20.

In FIG. 17, the signal Sig is input to the coarse delay circuits 10 and 10main. Similarly, the clock signal CLK is input to the coarse delay circuit 10 and the fine delay circuit 20 and the coarse delay circuit 10main and the fine delay circuit 20main.

The output signal out output from the fine delay circuit 20main is supplied to the LD driver 40. The LD driver 40 generates, based on the supplied output signal out, a drive signal for driving the LD 41. The LD 41 is driven according to the drive signal and emits light.

On the other hand, the output signal out output from the fine delay circuit 20 is supplied to a replica LD driver 40rep (a replication drive circuit). The replica LD driver 40rep has, for example, a configuration obtained by replicating the function of the LD driver 40. For example, the replica LD driver 40rep is configured such that a load viewed from a circuit in the preceding stage (for example, the fine delay circuit 20) is substantially equal to a load of the LD driver 40 viewed from a circuit in the preceding stage (for example, the fine delay circuit 20main).

In FIG. 17A, an output signal output from the replica LD driver 40rep is input to the phase comparison circuit 30. That is, an output signal output from the replica LD driver 40rep based on the output signal out output from the fine delay circuit 20 is input to the phase comparison circuit 30. The phase comparison circuit 30 generates a coarse control signal and a fine control signal based on the signal Sig and the output signal from the replica LD driver 40rep. The generated coarse control signal is supplied to the respective the coarse delay circuits 10 and 10main. Similarly, the generated fine control signal is supplied to the respective fine delay circuits 20 and 20main.

In such a configuration, the light source drive circuit 1b generates a coarse control signal and a fine control signal in the phase comparison circuit 30 based on the input signal Sig and the output signal of the replica LD driver 40rep and fixes a delay by the coarse delay circuit 10 and the fine delay circuit 20 with the generated coarse control signal and the generated fine control signal. The light source drive circuit 1b controls an amount of delay by the coarse delay circuit 10main and the fine delay circuit 20main with the coarse control signal and the fine control signal. Since the phases are synchronized based on the output signal of the replica LD driver 40rep, it is possible to adjust a phase in a position closer to the LD driver 40.

Here, for example, a case is conceived in which an LD array in which a plurality of LDs 41 are arranged in an array. The LD driver 40 is provided for each of the plurality of LDs 41 included in the LD array. In this case, delays in the LD drivers 40 greatly fluctuate because of the influence of fluctuations in temperature, a power supply voltage, and the like. Delays of the output signal out supplied to the LD drivers 40 are adjusted with delays by the coarse delay circuit 10 and the fine delay circuit 20 using the coarse delay circuit 10main and the fine delay circuit 20main. Consequently, the delays in the LD drivers 40 are fixed to the delays by the coarse delay circuit 10 and the fine delay circuit 20. This enables stable driving of the plurality of LDs 41.

Note that, as a configuration corresponding to the plurality of LDs 41 in this case, a configuration is conceivable in which a plurality of sets respectively including the LD drivers 40 and the LDs 41 are connected in parallel and an output signal out output from the fine delay circuit 20main is supplied to the plurality of sets in common. Not only this, but a configuration is also conceivable in which configurations by the coarse delay circuit 10main and the fine delay circuit 20main are respectively provided for each of the plurality of sets. Further, a configuration is also conceivable in which the fine delay circuits 20main are provided in the respective plurality of sets and one coarse delay circuit 10main is provided in the plurality of fine delay circuits 20main in common.

(Another Example of the Second Modification of the First Embodiment)

FIG. 17B is a block diagram illustrating a configuration of another example of the light source drive circuit according to the second modification of the first embodiment. In the light source drive circuit 1b illustrated in FIG. 17A explained above, the output signal output from the replica LD driver 40rep is input to the phase comparison circuit 30. In contrast, a light source drive circuit 1b′ illustrated in FIG. 17B inputs the output signal out output from the fine delay circuit 20 to the phase comparison circuit 30. The phase comparison circuit 30 generates a coarse control signal and a fine control signal based on the signal Sig and the output signal out. According to the configuration illustrated in FIG. 17B, a load of the fine delay circuit 20main and a load of the fine delay circuit 20 can be made substantially equal.

(3-3. Third Modification of the First Embodiment of the Present Disclosure)

Next, a third modification of the first embodiment of the present disclosure is explained. In the third modification of the first embodiment, an offset with respect to a delay amount can be added to at least one of the coarse delay circuit 10main and the fine delay circuit 20main in contrast to the configuration according to the second modification of the first embodiment explained above.

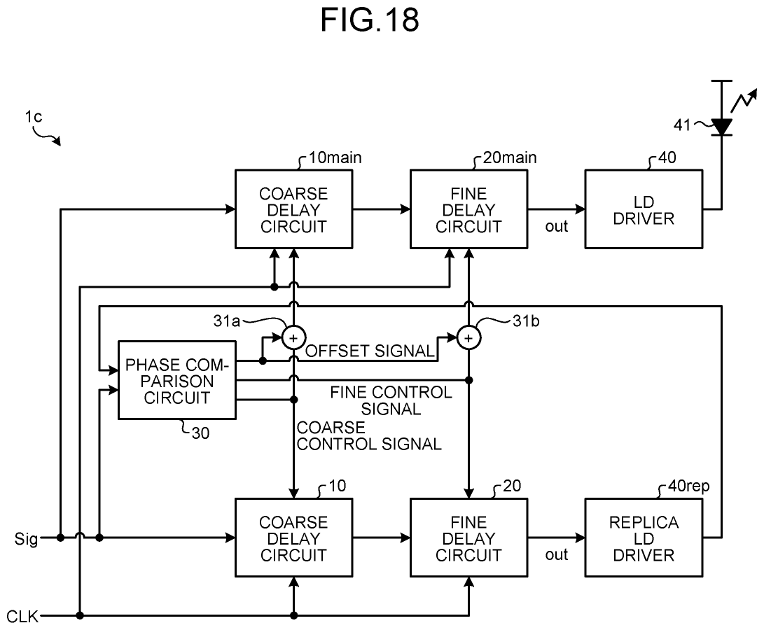

FIG. 18 is a block diagram illustrating a configuration of an example of a light source drive circuit according to the third modification of the first embodiment. In a light source drive circuit 1c illustrated in FIG. 18, an adder 31a is provided for a path for supplying a coarse control signal from the phase comparison circuit 30 to the coarse delay circuit 10. The adder 31a adds an offset signal to the coarse control signal and supplies the coarse control signal to the coarse delay circuit 10main. Similarly, an adder 31b is provided for a path for supplying a fine control signal from the phase comparison circuit 30 to the fine delay circuit 20. The adder 31b adds an offset signal to the fine control signal and supplies the fine control signal to the fine delay circuit 20main.

Here, the offset signal is a fixed value indicating an offset value with respect to a delay amount controlled by a coarse control signal and a fine control signal. The offset signal is generated in the control signal generation unit 301 included in the phase comparison circuit 30. The coarse delay circuit 10main and the fine delay circuit 20main give a delay to an input signal according to the coarse control signal and the fine control signal obtained by adding the offset value to the delay amount by the adders 31a and 31b.

As explained above, in the third modification of the first embodiment, the offset value is added by the offset signal to the delay amount indicated by the coarse control signal and the fine control signal. Consequently, it is possible to differentiate a shift amount of the output signal out supplied to the LD driver 40 with respect to a phase and a shift amount of the output signal out supplied to the replica LD driver 40rep with respect to a phase.

(3-4. Fourth Modification of the First Embodiment of the Present Disclosure)

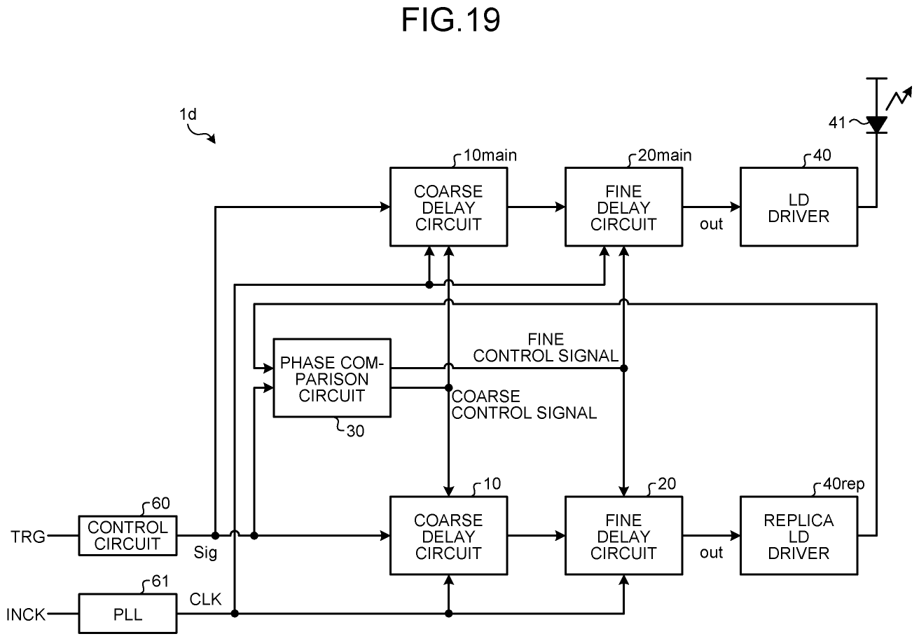

Next, a fourth modification of the first embodiment is explained. FIG. 19 is a block diagram illustrating a configuration of an example of a light source drive circuit according to the fourth modification of the first embodiment.

In FIG. 19, a light source drive circuit 1d is an example in which a control circuit 60 and a PLL (Phase Locked Loop) are added to the configuration of the light source drive circuit 1b illustrated in FIG. 17. A trigger signal TRG is input to the control circuit 60 at any timing. The control circuit 60 generates the signal Sig serving as a PWM signal having a predetermined cycle according to the timing when the trigger signal TRG is input. The control circuit 60 supplies the generated signal Sig to each of the coarse delay circuits 10 and 10main.

An internal clock signal INCK is input to a PLL 61. As an example, the internal clock signal INCK is a clock signal used in a device (such as a distance measuring device) in which the light source drive circuit 1d is incorporated. The PLL 61 generates, based on the internal clock signal INCK, the clock signal CLK having the same cycle as the signal Sig. The PLL 61 supplies the generated clock signal CLK respectively to the coarse delay circuits 10 and 10main and the fine delay circuits 20 and 20main.

An operation of the light source drive circuit 1d itself is the same as the operation explained with reference to FIG. 17A except an operation relating to the control circuit 60 and the PLL 61. Therefore, explanation of the operation is omitted here.

As explained above, even when light emission timing of the LD 41 is instructed by the trigger signal TRG input at any timing, the light emission timing of the LD 41 can be controlled in units finer than the clock signal CLK.

For example, in the configuration in which the LD drivers are provided in the respective plurality of LDs 41 included in the LD array as explained above, a delay of the output signal out supplied to the LD drivers 40 can be adjusted by a delay by the coarse delay circuit 10 and the fine delay circuit 20. Consequently, a delay in the LD drivers 40 with respect to the trigger signal TRG is fixed to the delay by the coarse delay circuit 10 and the fine delay circuit 20 and it is possible to stably drive the plurality of LDs 41.

### 4. Second Embodiment of the Present Disclosure

Next, a second embodiment of the present disclosure is explained. The second embodiment relates to implementation of the LD driver 40 and the LD 41 according to the first embodiment and the modifications thereof explained above.

In the following explanation, it is assumed that an LD array in which the plurality of LDs 41 are arrayed in an array is used and the LD drivers 40 are provided for the respective plurality of LDs 41 included in the LD array.

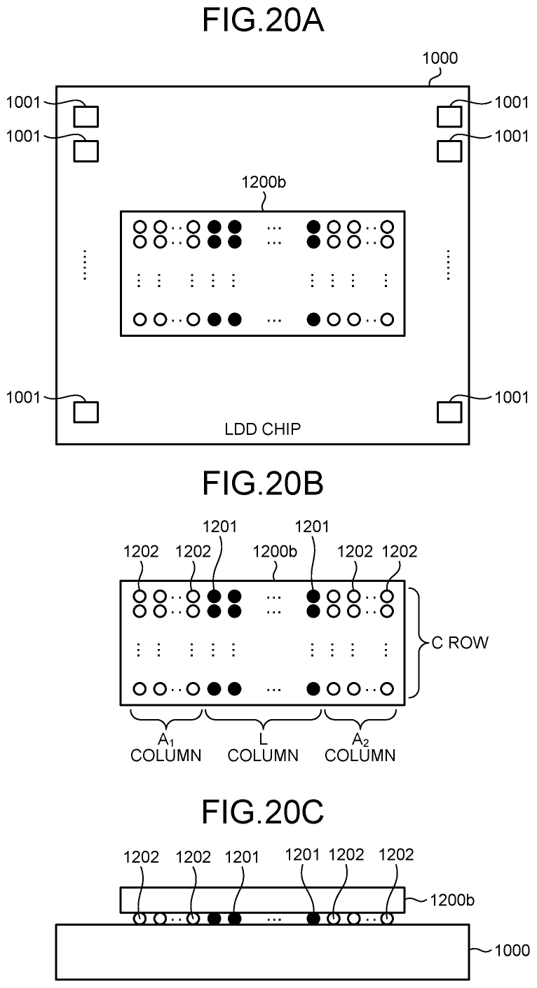

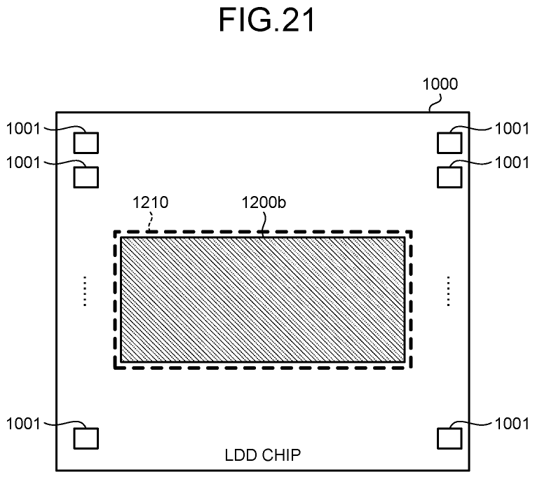

FIG. 20A to FIG. 20C are diagrams schematically illustrating implementation examples of the LD driver 40 and an LD array 1200b according to the second embodiment. In the examples illustrated in FIG. 20A to FIG. 20C, the LD array 1200b and other components included in the light source drive circuit 1 are formed on different substrates.

FIG. 20A is a diagram schematically illustrating a state in which the LD array 1200b is disposed on an LDD (laser diode driver) chip 1000 on which elements included in the LD driver 40 are disposed, applicable to the second embodiment. FIG. 20A illustrates a state in which the LDD chip 1000 and the LD array 1200b are viewed from a surface (assumed to be an upper surface) on which light emitting units of the LDs 41 (not illustrated) included in the LD array 1200b are disposed Note that, in FIG. 20A and FIG. 20B referred to below, the LD array 1200b is illustrated in a state in which a side (a rear surface) connected to the LDD chip 1000 is seen through from the upper surface side on which the light emitting units of the LDs 41 are disposed.

The LDD chip 1000 is one semiconductor chip and is connected to an external circuit by wire bonding to a plurality of pads 1001 disposed in a peripheral portion. For example, electric power having a voltage V_{DD} is supplied to the LDD chip 1000 from the outside via the pads 1001.

FIG. 20B is a diagram schematically illustrating a configuration of the LD array 1200b applicable to the second embodiment. As illustrated in FIG. 20B, cathode terminals 1201 of the respective plurality of LDs 41 included in the LD array 1200b and anode terminals 1202 common to the plurality of LDs 41 are disposed to be aligned on the rear surface of the LD array 1200b.

In the example illustrated in FIG. 20B, when the lateral direction in the figure is represented as a row and the longitudinal direction in the figure is represented as a column, the cathode terminals 1201 are disposed in the center of the LD array 1200b by a lattice-like array of C rows×L columns. That is, in this example, (C×L) LDs 41 are disposed on the LD array 1200b. The anode terminals 1202 are disposed in lattice-like array including C rows×A₁ columns on the left end side and C rows×A₂ columns on the right end side of the LD array 1200b.

Here, by forming, with the plurality of anode terminals 1202, a plurality of coupling portions to which the anodes of the LDs 41 are connected in common, it is possible to reduce connection resistance in connecting the anodes to the LDD chip 1000.

FIG. 20C is a side view of structure including the LDD chip 1000 and the LD array 1200b, which is applicable to the second embodiment, viewed from the lower end side of FIG. 20A. As explained above, the LDD chip 1000 and the LD array 1200b have structure in which the LD array 1200b is stacked on the LDD chip 1000. The cathode terminals 1201 and the anode terminals 1202 are connected to the LDD chip 1000 by, for example, a micro-bump.

FIG. 21 is a schematic diagram illustrating an example of disposition positions of the LD drivers 40 according to the second embodiment with respect to the LDD chip 1000. In the second embodiment, the respective LD drivers 40 respectively corresponding to the LDs 41 included in the LD array 1200b are disposed in a region 1210 corresponding to the LD array 1200b in the LDD chip 1000.

Not only this, but a part of the LD drivers 40 may be disposed in the region 1210. A part or all of the components of the light source drive circuit 1 may be disposed in the region 1210 in addition to the LD drivers 40 or other components may be further disposed in the region 1210.

### 5. Third Embodiment of the Present Disclosure

Next, a third embodiment of the present disclosure is explained. The third embodiment is an example in which any one of the light source drive circuits 1 and 1a to 1d according to the present disclosure explained above is applied to a distance measuring device that performs distance measurement by an indirect time of flight (ToF) scheme.

(5-1. Schematic Explanation of the Indirect ToF)

First, the distance measurement by the indirect ToF is schematically explained.

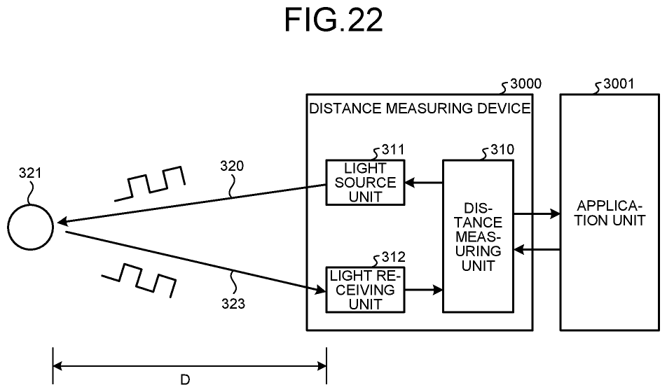

FIG. 22 is a block diagram illustrating a configuration of an example of a distance measuring device applicable to the third embodiment. In FIG. 22, an application unit 3001 is realized by, for example, a program operating on a CPU (Central Processing Unit), requests a distance measuring device 3000 to execute distance measurement, and receives distance information or the like, which is a result of the distance measurement, from the distance measuring device 3000.

The distance measuring device 3000 includes a light source unit 311, a light receiving unit 312, and a distance measuring unit 310. The light source unit 311 includes, for example, a light emitting element that emits light having a wavelength in an infrared region and a drive circuit that drives the light emitting element to emit light. As the light emitting element included in the light source unit 311, a VCSEL (Vertical Cavity Surface Emitting LASER), which is a surface light source in which a plurality of light emitting elements are formed in an array, can be applied. Not only this, but LEDs (Light Emitting Diodes) arrayed in an array may be applied as the light emitting element included in the light source unit 311.

In the following explanation, unless particularly described otherwise, “the light emitting element of the light source unit 311 emits light” is described as “the light source unit 311 emits light” or the like.

The light receiving unit 312 includes, for example, a plurality of light receiving elements capable of detecting light having a wavelength in an infrared region and a signal processing circuit that outputs a pixel signal corresponding to lights detected by the respective plurality of light receiving elements. The plurality of light receiving elements are arrayed in an array in the light receiving unit 312 to form a light receiving surface. A photodiode can be applied as the light receiving element included in the light receiving unit 312. In the following explanation, unless particularly described otherwise, “the light receiving element included in the light receiving unit 312 receives light” is described as “the light receiving unit 312 receives light” or the like.

The distance measuring unit 310 executes distance measurement processing in the distance measuring device 3000 in response to, for example, a distance measurement instruction from the application unit 3001. For example, the distance measuring unit 310 generates a light source control signal for driving the light source unit 311 and supplies the light source control signal to the light source unit 311. The distance measuring unit 310 controls light reception by the light receiving unit 312 in synchronization with a light source control signal supplied to the light source unit 311. For example, the distance measuring unit 310 generates an exposure control signal for controlling an exposure period in the light receiving unit 312 in synchronization with the light source control signal and supplies the exposure control signal to the light receiving unit 312. The light receiving unit 312 outputs an effective pixel signal within the exposure period indicated by the exposure control signal.

The distance measuring unit 310 calculates distance information based on a pixel signal output from the light receiving unit 312 according to light reception. The distance measuring unit 310 can also generate predetermined image information based on the pixel signal. The distance measuring unit 310 passes distance information and image information calculated and generated based on the pixel signal to the application unit 3001.

In such a configuration, the distance measuring unit 310 generates, for example, according to an instruction to execute distance measurement from the application unit 3001, a light source control signal for driving the light source unit 311 and supplies the light source control signal to the light source unit 311. Here, the distance measuring unit 310 generates a light source control signal modulated into a rectangular wave having a predetermined duty by PWM, and supplies the light source control signal to the light source unit 311. At the same time, the distance measuring unit 310 controls light reception by the light receiving unit 312 based on an exposure control signal synchronized with the light source control signal.

In the distance measuring device 3000, the light source unit 311 blinks and emits light according to a predetermined duty in response to the light source control signal generated by the distance measuring unit 310. The light emitted in the light source unit 311 is emitted from the light source unit 311 as emission light 320. The emission light 320 is reflected by, for example, a measurement object 321 and is received by the light receiving unit 312 as reflected light 323. The light receiving unit 312 supplies a pixel signal corresponding to the light reception of the reflected light 323 to the distance measuring unit 310. Note that, actually, the light receiving unit 312 receives ambient environmental light other than the reflected light 323 and the pixel signal includes a component of the environmental light together with a component of the reflected light 323.

The distance measuring unit 310 executes the light reception by the light receiving unit 312 a plurality of times in different phases. The distance measuring unit 310 calculates a distance D to the measurement object based on the difference between pixel signals due to light receptions in different phases. The distance measuring unit 310 calculates, based on the difference between the pixel signals, first image information obtained by extracting the component of the reflected light 323 and second image information including the component of the reflected light 323 and the component of the environmental light. In the following explanation, the first image information is referred to as direct reflected light information and the second image information is referred to as RAW image information.

(Distance Measurement by an Indirect ToF Scheme Applicable to the Embodiments)

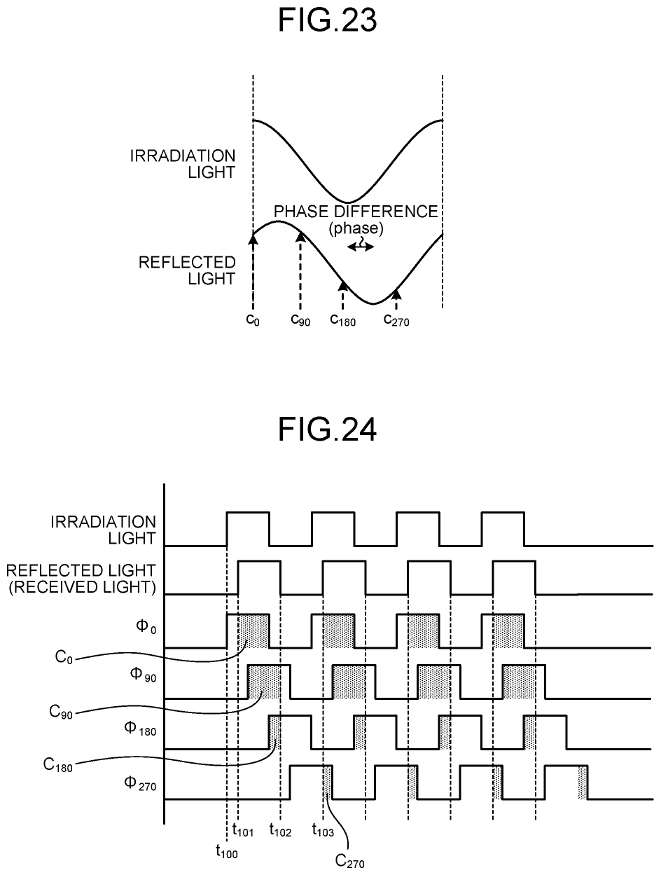

Next, distance measurement by an indirect ToF scheme applicable to the embodiments is explained. FIG. 23 is a diagram for explaining a principle of the indirect ToF scheme. In FIG. 23, light modulated by a sine wave is used as the emission light 320 emitted from the light source unit 311. Ideally, the reflected light 323 is a sine wave having a phase difference phase corresponding to the distance D with respect to the emission light 320.

The distance measuring unit 310 performs, in different phases, a plurality of times of sampling on the pixel signal that has received the reflected light 323 and acquires, in every sampling, a light amount value indicating a light amount. In an example illustrated in FIG. 23, light amount values C₀, C₉₀, C₁₈₀, and C₂₇₀ are respectively acquired in phases of a phase 0°, a phase 90°, a phase 180°, and a phase 270°, which are different by a phase of 90° with respect to the emission light 320. In the indirect ToF scheme, distance information is calculated based on a difference between light amount values of a set of phases different by 180° among the phases 0°, 90°, 180°, and 270°.

A method of calculating distance information in the indirect ToF scheme is more specifically explained with reference to FIG. 24. FIG. 24 is a diagram illustrating an example of a case in which the emission light 320 from the light source unit 311 is a rectangular wave modulated by PWM. In FIG. 24, the emission light 320 by the light source unit 311 and the reflected light 323 reaching the light receiving unit 312 are illustrated from the top. As illustrated at the top of FIG. 24, the light source unit 311 periodically flashes at a predetermined duty to emit the emission light 320.

FIG. 24 further illustrates exposure control signals Φ₀, Φ₉₀, Φ₁₈₀, and Φ₂₇₀ respectively in a phase 0°, a phase 90°, a phase 180°, and a phase 270° of the light receiving unit 312. For example, a period in which the exposure control signals are in a high (High) state is an exposure period in which the light receiving unit 312 outputs an effective pixel signal.

In the example illustrated in FIG. 24, the emission light 320 is emitted from the light source unit 311 at a point in time t₁₀₀ and the reflected light 323 of the emission light 320 reflected by the measurement object reaches the light receiving unit 312 at a point in time tin after a delay corresponding to the distance D to the measurement object from the point in time t₁₀₀.

On the other hand, in the light receiving unit 312, according to the exposure control signal from the distance measuring unit 310, an exposure period in the phase 0° is started in synchronization with the point in time t₁₀₀ of emission timing of the emission light 320 in the light source unit 311. Similarly, in the light receiving unit 312, exposure periods in the phase 90°, the phase 180°, and the phase 270° are started according to the exposure control signals from the distance measuring unit 310. Here, the exposure periods in the phases conform to the duty of the emission light 320. Note that, in the example illustrated in FIG. 24, for explanation, the exposure periods in the phases are illustrated as being temporally parallel. However, actually, in the light receiving unit 312, the exposure periods inf the phases are sequentially designated and the light amount values C₀, C₉₀, C₁₈₀, and C₂₇₀ in the phases are acquired.

In the example illustrated in FIG. 24, arrival timings of the reflected light 323 is points in time t₁₀₁, t₁₀₂, t₁₀₃, and the like, and the light amount value C₀ in the phase 0° is acquired as an integral value of a received light amount from the point in time t₁₀₀ to the end time point of the exposure period including the point in time t₁₀₀ in the phase 0°. On the other hand, in the phase 180° different from the phase 0° by a phase of 180°, the light amount value C₁₈₀ is acquired as an integral value of a received light amount from a start point in time of an exposure period in the phase 180° to the point in time t₁₀₂ of the falling of the reflected light 323 included in the exposure period.

For the phase 90° and the phase 270° different from the phase 90° by a phase of 180°, as in the case of the phases 0° and 180° explained above, integrated values of received light amounts in periods in which the reflected light 323 arrives within the respective exposure periods are acquired as the light amount values C₉₀ and C₂₇₀.

Among these light amount values C₀, C₉₀, C₁₈₀, and C₂₇₀, as shown in the following Expressions (1) and (2), the difference I and the difference Q are calculated based on a combination of light quantity values, phases of which are different by 180°.

I=C₀−C₁₈₀ (1)

Q=C₉₀−C₂₇₀ (2)

Based on these differences I and Q, the phase difference phase is calculated by the following Expression (3). Note that, in Expression (3), the phase difference phase is defined in a range of (0≤phase<2π).

phase=tan⁻¹(Q/I) (3)

Distance information Depth is calculated by the following Expression (4) using the phase difference phase and a predetermined coefficient range.

Depth=(phase×range)/2π (4)

Further, based on the differences I and Q, a component of the reflected light 323 (directly reflected light information) can be extracted from components of the light received by the light receiving unit 312. Direct reflected light information DiRefl is calculated by the following Expression (5) using the absolute values of the respective differences I and Q.

DiRefl=|I|+|Q| (5)

Note that the direct reflected light information DiRefl is also called Confidence information and can also be represented like the following Expression (6).

Confidence=√I²+√Q² (6)

RAW image information RAW can be calculated as an average value of the light amount values C₀, C₉₀, C₁₈₀, and C₂₇₀ as shown in the following Expression (7).

RAW=(C₀+C₉₀+C₁₈₀+C₂₇₀)/4 (7)

(5-2. Configuration Example for Implementing the Indirect ToF)

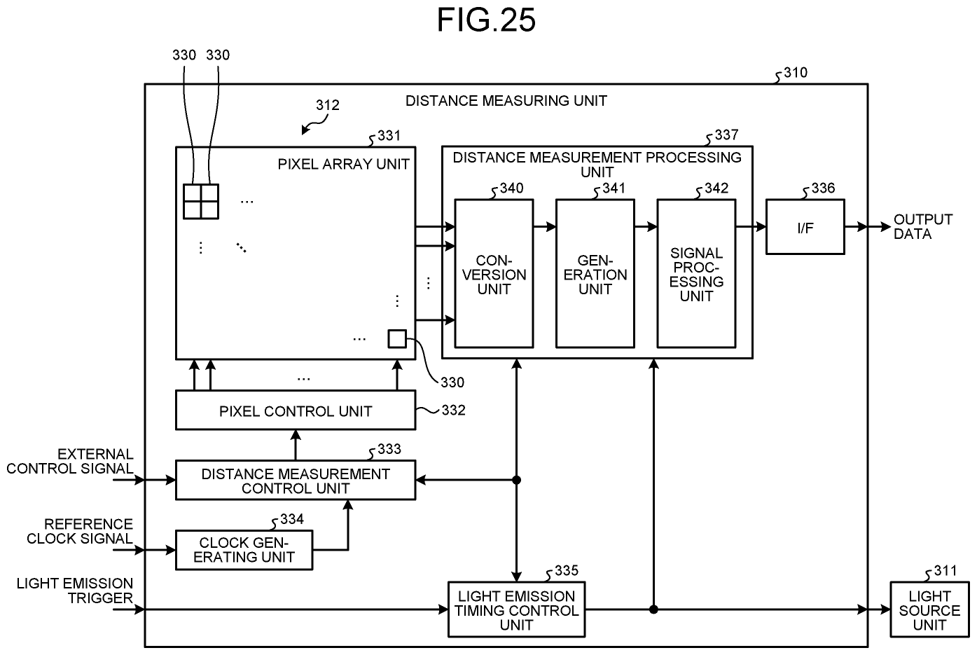

Next, a configuration example of a distance measuring device applicable to the third embodiment is explained. FIG. 25 is a block diagram illustrating, more in detail, a configuration example of a distance measuring unit 310 applicable to the third embodiment. In FIG. 25, the distance measuring unit 310 includes a pixel array unit 331, a distance measurement processing unit 337, a pixel control unit 332, a distance measurement control unit 333, a clock generating unit 334, a light emission timing control unit 335, and an interface (I/F) 336. The pixel array unit 331, the distance measurement processing unit 337, the pixel control unit 332, the distance measurement control unit 333, the clock generating unit 334, the light emission timing control unit 335, and the interface 336 are disposed, for example, on one semiconductor chip.

In FIG. 25, the distance measurement control unit 333 controls an operation of the entire distance measuring unit 310 according to, for example, a program incorporated in advance. The distance measurement control unit 333 can also execute control corresponding to an external control signal supplied from the outside (for example, an overall control unit that performs control of the entire distance measuring device 3000).

The clock generating unit 334 generates, based on a reference clock signal (for example, the internal clock signal INCK) supplied from the outside, one or more clock signals used in the distance measuring unit 310. For example, the clock generating unit 334 includes the PLL 61 explained above and can generate the clock signal CLK based on the reference clock signal. The clock signal CLK is supplied to the light emission timing control unit 335 via the distance measurement control unit 333.

The light source drive circuit 1d explained in the fourth modification of the first embodiment is applied to the light emission timing control unit 335. The light emission timing control unit 335 generates a light emission control signal (for example, the output signal out) indicating light emission timing and light emission duration according to a light emission trigger signal (the trigger signal TRG in the example of the light source drive circuit 1d) supplied from the outside. The light emission control signal is supplied to the light source unit 311 and also supplied to the distance measurement processing unit 337.

Note that any one of the light source drive circuits 1 and 1a to 1c according to the first embodiment and the first to third modifications thereof can also be applied to the light emission timing control unit 335. In this case, the light emission timing control unit 335 includes a function equivalent to the function of the control circuit 60 explained above and generates, according to timing when the light emission trigger signal is supplied, the signal Sig having the same cycle as the cycle of the clock signal CLK generated by the clock generating unit 334.

The pixel array unit 331 includes a plurality of pixel circuits 330 arranged in a matrix array and respectively including light receiving elements. Operations of the pixel circuits 330 are controlled by the pixel control unit 332 that follows an instruction of the distance measurement control unit 333. For example, the pixel control unit 332 can control reading of pixel signals from the pixel circuits 330 for each block including (p×q) pixel circuits 330: p in the row direction and q in the column direction. The pixel control unit 332 can scan the pixel circuits 330 in the row direction and further scan the pixel circuits 330 in the column direction in units of the block and read pixel signals from the pixel circuits 330. Not only this, but the pixel control unit 332 can respectively independently control the pixel circuits 330.

Further, the pixel control unit 332 can set a predetermined region of the pixel array unit 331 as a target region and set the pixel circuits 330 included in the target region as target pixel circuits 330 from which pixel signals are read. Furthermore, the pixel control unit 332 can collectively scan a plurality of rows (a plurality of lines), further scan the rows in the column direction, and read pixel signals from the pixel circuits 330.

The pixel signals read from the pixel circuits 330 are supplied to the distance measurement processing unit 337. The distance measurement processing unit 337 includes a conversion unit 340, a generation unit 341, and a signal processing unit 342.

The pixel signals read from the pixel circuits 330 and output from the pixel array unit 331 are supplied to the conversion unit 340. Here, the pixel signals are asynchronously read from the pixel circuits 330 included in the target region and supplied to the conversion unit 340. That is, the pixel signals are read and output from the light receiving elements according to timing when light is received in the pixel circuits 330 included in the target region.

The conversion unit 340 converts the pixel signals supplied from the pixel array unit 331 into digital information. That is, the pixel signals supplied from the pixel array unit 331 are output according to timing when light is received by the light receiving elements included in the pixel circuits 330 corresponding to the pixel signals. The conversion unit 340 converts the supplied pixel signals into time information indicating the timing.

The generation unit 341 generates a histogram based on the time information into which the pixel signals are converted by the conversion unit 340. Here, the generation unit 341 includes a counter, classifies the time information based on a class (bin (bins)) corresponding to a unit time T_{P} set as predetermined, counts the time information with the counter for each bin, and generates a histogram.

The signal processing unit 342 performs predetermined arithmetic processing based on data of the histogram generated by the generation unit 341 and calculates, for example, distance information. For example, the signal processing unit 342 calculates, based on the data of the histogram generated by the generation unit 341, an amount of light N received in the unit time T_{P}. The signal processing unit 342 can obtain the distance D on the basis of the light amount of light N.

Distance measurement data indicating the distance D calculated by the signal processing unit 342 is supplied to the interface 336. The interface 336 outputs the distance measurement data supplied from the signal processing unit 342 to the outside as output data. As the interface 336, for example, an MIPI (registered trademark) (Mobile Industry Processor Interface) can be applied.

Note that, in the above explanation, the distance measurement data indicating the distance D calculated by the signal processing unit 342 is output to the outside via the interface 336. However, this is not limited to this example. That is, histogram data, which is the data of the histogram generated by the generation unit 341, may be output to the outside from the interface 336. The histogram data output from the interface 336 is supplied to, for example, an external information processing device and processed as appropriate.

In the configuration explained above, by applying any one of the light source drive circuits 1 and 1a to 1d explained in the first embodiment and the modifications thereof to the light emission timing control unit 335, the light emission timing in the light source unit 311 corresponding to the input of the light emission trigger can be controlled with higher accuracy. By controlling the light emission timing with high accuracy, distance measurement can be increased in accuracy. The light emission timing by the light source unit 311 is affected by voltage fluctuation and a temperature environment. However, by controlling a delay in the fine delay circuit 20, it is also possible to adjust the light emission timing by the influence.

Note that, in the above explanation, it is assumed that the light source drive circuits 1 and 1a to 1d according to the present disclosure are applied to the distance measuring device that performs distance measurement by the indirect ToF scheme. However, this is not limited to this example. For example, the light source drive circuits 1 and 1a to 1d according to the present disclosure can also be applied to a distance measuring device that performs distance measurement by the direct ToF scheme for performing distance measurement based on a time from when light is emitted from a light source to when the light is reflected by a measurement object and received.

Note that the effects described in this specification are only illustrations and are not limited. Other effects may be present.

Note that the present technique can also take the following configurations.
(1) A light source drive circuit comprising:
   a first delay circuit that gives, based on a clock signal, a delay to an input signal with first time resolution; and
   a second delay circuit that is connected in series to the first delay circuit, gives, based on the clock signal, a delay to an input signal with second time resolution having accuracy different from accuracy of the first time resolution, and outputs the signal as a signal for driving a light source.
(2) The light source drive circuit according to the above (1), further comprising
   a phase comparison circuit that compares a first phase based on the output of the second delay circuit and a second phase based on the signal input to the first delay circuit and generates, based on a comparison result, a first control signal for controlling the delay by the first delay circuit and a second control signal for controlling the delay by the second delay circuit.
(3) The light source drive circuit according to the above (1) or (2), wherein
   the second time resolution is more accurate than the first time resolution.
(4) The light source drive circuit according to the above (3), further comprising
   a synchronization circuit that synchronizes the output of the first delay circuit with the signal delayed by the second delay circuit.
(5) The light source drive circuit according to any one of the above (2) to (4), wherein
   the phase comparison circuit performs
   counting according to a difference between the first phase and the second phase and outputs the first control signal and the second control signal based on a count value obtained by the counting.
(6) The light source drive circuit according to the above (5), wherein
   the phase comparison circuit performs the counting using an n-bit counter,
   outputs the second control signal according to a change in a value of lower-order m bits (m<n) of the count value, and
   outputs the first control signal according to a change in a value of higher-order (n−m) bits of the count value.
(7) The light source drive circuit according to the above (5), wherein
   the phase comparison circuit performs
   the counting using an n-bit counter,
   outputs the second control signal according to a change in a value of lower-order m bits among values of higher-order k bits (k<n) of the count value, and
   outputs the first control signal according to a change in a value of higher-order (n−k) bits of the count value.
(8) The light source drive circuit according to any one of the above (2) to (7), further comprising
   a drive circuit that drives the light source according to the output of the second delay circuit.
(9) The light source drive circuit according to any one of the above (2) to (7), further comprising:
   a third delay circuit that gives, based on the clock signal and the first control signal, a delay to an input signal with the first time resolution;
   a fourth delay circuit that is connected in series to the third delay circuit and gives, based on the clock signal and the second control signal, a delay to an input signal with the second time resolution;
   a drive circuit that drives the light source according to an output of the fourth delay circuit; and
   a replication drive circuit that replicates a function of the drive circuit; wherein
   the output of the second delay circuit is supplied to the replication drive circuit, and
   the phase comparison circuit compares a phase of an output of the replication drive circuit based on the output of the second delay circuit as the first phase with the second phase.
(10) The light source drive circuit according to any one of the above (2) to (7), further comprising:
   a third delay circuit that gives, based on the clock signal and the first control signal, a delay to an input signal with the first time resolution;
   a fourth delay circuit that is connected in series to the third delay circuit and gives, based on the clock signal and the second control signal, a delay to an input signal with the second time resolution;
   a drive circuit that drives the light source according to an output of the fourth delay circuit; and
   a replication drive circuit that replicates a function of the drive circuit, wherein
   the output of the second delay circuit is supplied to the replication drive circuit.
(11) The light source drive circuit according to the above (9) or (10), further comprising
   an adder that adds an offset to a delay amount by the first control signal and a delay amount by the second control signal.
(12) The light source drive circuit according to any one of the above (2) to (11), further comprising
   a signal generation circuit that generates, based on the clock signal, a plurality of clock signals having different phases at every 90°, wherein
   the second delay circuit gives,
   according to the second control signal, a delay to the input signal at a phase angle at least in a range of 0° to 90° using the clock signal generated by the signal generation circuit.
(13) The light source drive circuit according to the above (12), further comprising
   a first selector that selects, according to the first control signal, which of the plurality of clock signals generated by the signal generation circuit is supplied to the first delay circuit as the clock signal.
(14) The light source drive circuit according to any one of the above (2) to (13), wherein
   the first delay circuit includes:
   a plurality of delay elements connected in series that respectively delay input signals according to the clock signal; and
   a second selector that selects, according to the first control signal, which output of the plurality of delay elements and a head delay element among the plurality of delay elements is supplied to the second delay circuit.
(15) The light source drive circuit according to any one of the above (2) to (13), wherein
   the first delay circuit combines an inverter circuit and a variable capacitor, capacitance of which is varied according to the first control signal, and gives a delay to the input signal.
(16) The light source drive circuit according to any one of the above (2) to (13), wherein
   the first delay circuit gives a delay to the input signal using an inverter circuit subjected to current limitation according to the first control signal.
(17) The light source drive circuit according to any one of the above (2) to (13), wherein
   the first delay circuit
   combines an inverter circuit and an RC circuit in which a resistor and a capacitor are connected in series, time constants of the resistor and the capacitor being respectively varied according to the first control signal, and gives a delay to the input signal.
(18) A distance measuring device comprising:
   a light source unit that emits light according to a drive signal;
   a light receiving unit that receives the light;
   a distance measuring unit that performs distance measurement based on light emission timing when the light is emitted by the light source unit and light reception timing when the light is received by the light receiving unit;
   a first delay circuit that gives, based on a clock signal, a delay to an input signal with first time resolution;
   a second delay circuit that is connected in series to the first delay circuit and gives, based on the clock signal, a delay to an input signal with second time resolution having accuracy different from accuracy of the first time resolution; and
   a drive circuit that generates, according to an output of the second delay circuit, the drive signal for driving the light source unit.
(19) The distance measuring device according to the above (18), wherein the distance measuring unit performs the distance measurement with an indirect time of flight (ToF) scheme.

### REFERENCE SIGNS LIST

1, 1a, 1b, 1c, 1d, 500 LIGHT SOURCE DRIVE CIRCUIT
10, 10a, 10b, 10c, 10main COARSE DELAY CIRCUIT
20, 20a, 20b, 20main FINE DELAY CIRCUIT
30 PHASE COMPARISON CIRCUIT
31a, 31b ADDER
40 LD DRIVER
40rep REPLICA LD DRIVER
41 LD
60 CONTROL CIRCUIT
61 PLL
100, 201, 300 FF CIRCUIT
101, 120, 240 SELECTOR
111, 115 VARIABLE CAPACITOR
112a, 112b CURRENT LIMITING CIRCUIT
113 CAPACITOR
114 VARIABLE RESISTOR
200, 200a, 200b PHASE CHANGING CIRCUIT
210a, 210b I/Q GENERATION CIRCUIT
220, 220₁, 220₂, 220₃, 220₄ PHASE INTERPOLATION CIRCUIT
221a, 221b, 222 INVERTER CIRCUIT
230 PHASE ROTATOR
301 CONTROL SIGNAL GENERATION UNIT
310 DISTANCE MEASURING UNIT
311 LIGHT SOURCE UNIT
312 LIGHT RECEIVING UNIT
331 PIXEL ARRAY UNIT
333 DISTANCE MEASUREMENT CONTROL UNIT
334 CLOCK GENERATING UNIT
335 LIGHT EMISSION TIMING CONTROL UNIT
337 DISTANCE MEASUREMENT PROCESSING UNIT
1000 LDD CHIP
1200b LD ARRAY
1201 CATHODE TERMINAL
1202 ANODE TERMINAL
3000 DISTANCE MEASURING DEVICE
3010 COUNTER

1. A light source drive circuit comprising:
a first delay circuit that gives, based on a clock signal, a delay to an input signal with first time resolution; and
a second delay circuit that is connected in series to the first delay circuit, gives, based on the clock signal, a delay to an input signal with second time resolution having accuracy different from accuracy of the first time resolution, and outputs the signal as a signal for driving a light source.

2. The light source drive circuit according to claim 1, further comprising
a phase comparison circuit that compares a first phase based on the output of the second delay circuit and a second phase based on the signal input to the first delay circuit and generates, based on a comparison result, a first control signal for controlling the delay by the first delay circuit and a second control signal for controlling the delay by the second delay circuit.

3. The light source drive circuit according to claim 1, wherein
the second time resolution is more accurate than the first time resolution.

4. The light source drive circuit according to claim 3, further comprising
a synchronization circuit that synchronizes the output of the first delay circuit with the signal delayed by the second delay circuit.

5. The light source drive circuit according to claim 2, wherein
the phase comparison circuit performs
counting according to a difference between the first phase and the second phase and outputs the first control signal and the second control signal based on a count value obtained by the counting.

6. The light source drive circuit according to claim 5, wherein
the phase comparison circuit performs the counting using an n-bit counter,
outputs the second control signal according to a change in a value of lower-order m bits (m<n) of the count value, and
outputs the first control signal according to a change in a value of higher-order (n-m) bits of the count value.

7. The light source drive circuit according to claim 5, wherein
the phase comparison circuit performs
the counting using an n-bit counter,
outputs the second control signal according to a change in a value of lower-order m bits among values of higher-order k bits (k<n) of the count value, and
outputs the first control signal according to a change in a value of higher-order (n-k) bits of the count value.

8. The light source drive circuit according to claim 2, further comprising
a drive circuit that drives the light source according to the output of the second delay circuit.

9. The light source drive circuit according to claim 2, further comprising:
a third delay circuit that gives, based on the clock signal and the first control signal, a delay to an input signal with the first time resolution;
a fourth delay circuit that is connected in series to the third delay circuit and gives, based on the clock signal and the second control signal, a delay to an input signal with the second time resolution;
a drive circuit that drives the light source according to an output of the fourth delay circuit; and
a replication drive circuit that replicates a function of the drive circuit; wherein
the output of the second delay circuit is supplied to the replication drive circuit, and
the phase comparison circuit compares a phase of an output of the replication drive circuit based on the output of the second delay circuit as the first phase with the second phase.

10. The light source drive circuit according to claim 2, further comprising:
a third delay circuit that gives, based on the clock signal and the first control signal, a delay to an input signal with the first time resolution;
a fourth delay circuit that is connected in series to the third delay circuit and gives, based on the clock signal and the second control signal, a delay to an input signal with the second time resolution;
a drive circuit that drives the light source according to an output of the fourth delay circuit; and
a replication drive circuit that replicates a function of the drive circuit, wherein
the output of the second delay circuit is supplied to the replication drive circuit.

11. The light source drive circuit according to claim 9, further comprising
an adder that adds an offset to a delay amount by the first control signal and a delay amount by the second control signal.

12. The light source drive circuit according to claim 2, further comprising
a signal generation circuit that generates, based on the clock signal, a plurality of clock signals having different phases at every 90°, wherein
the second delay circuit gives,
according to the second control signal, a delay to the input signal at a phase angle at least in a range of 0° to 90° using the clock signal generated by the signal generation circuit.

13. The light source drive circuit according to claim 12, further comprising
a first selector that selects, according to the first control signal, which of the plurality of clock signals generated by the signal generation circuit is supplied to the first delay circuit as the clock signal.

14. The light source drive circuit according to claim 2, wherein
the first delay circuit includes:
a plurality of delay elements connected in series that respectively delay input signals according to the clock signal; and
a second selector that selects, according to the first control signal, which output of the plurality of delay elements and a head delay element among the plurality of delay elements is supplied to the second delay circuit.

15. The light source drive circuit according to claim 2, wherein
the first delay circuit combines an inverter circuit and a variable capacitor, capacitance of which is varied according to the first control signal, and gives a delay to the input signal.

16. The light source drive circuit according to claim 2, wherein
the first delay circuit gives a delay to the input signal using an inverter circuit subjected to current limitation according to the first control signal.

17. The light source drive circuit according to claim 2, wherein
the first delay circuit
combines an inverter circuit and an RC circuit in which a resistor and a capacitor are connected in series, time constants of the resistor and the capacitor being respectively varied according to the first control signal, and gives a delay to the input signal.

18. A distance measuring device comprising:
a light source unit that emits light according to a drive signal;
a light receiving unit that receives the light;
a distance measuring unit that performs distance measurement based on light emission timing when the light is emitted by the light source unit and light reception timing when the light is received by the light receiving unit;
a first delay circuit that gives, based on a clock signal, a delay to an input signal with first time resolution;
a second delay circuit that is connected in series to the first delay circuit and gives, based on the clock signal, a delay to an input signal with second time resolution having accuracy different from accuracy of the first time resolution; and
a drive circuit that generates, according to an output of the second delay circuit, the drive signal for driving the light source unit.

19. The distance measuring device according to claim 18, wherein the distance measuring unit performs the distance measurement with an indirect time of flight (ToF) scheme.
